(19) United States
(12) Patent Application Publication
(10) Pub. No.: US 2026/0006891 A1
(43) Pub. Date: Jan. 1, 2026

(54) SELECTIVE TEMPLATED ALIGNED AT RECESS DUAL METAL GATE PATTERNING

(71) Applicant: Intel Corporation, Santa Clara, CA (US)

(72) Inventors: Orb Acton, Portland, OR (US); Guowei Xu, Portland, OR (US); Niangao Duan, Portland, OR (US); Petr Novotny, Hillsboro, OR (US); Omair Saadat, Portland, OR (US); Gianna Di Francesco, Portland, OR (US); Lukas Baumgartel, Portland, OR (US); David Towner, Portland, OR (US); Oleg Golonzka, Beaverton, OR (US); Dax Crum, Beaverton, OR (US); Dan Lavric, Portland, OR (US); Angeline Smith, Hillsboro, OR (US); Joseph Saunders, Portland, OR (US)

(73) Assignee: Intel Corporation, Santa Clara, CA (US)

(21) Appl. No.: 18/759,202

(22) Filed: Jun. 28, 2024

(51) Int. Cl. H01L 21/8238; H01L 27/092; H01L 29/06; H01L 29/423; H01L 29/49; H01L 29/786

(52) U.S. Cl. CPC H10D 84/038; H10D 30/6735; H10D 30/6757; H10D 62/118; H10D 64/667; H10D 84/0167; H10D 84/0177; H10D 84/85

(57) ABSTRACT

Integrated circuit (IC) devices having shared, dual-metal gates for complementary transistors. An IC device includes a shared gate structure over first and second stacks of nanoribbons with complementary conductivities and a substrate, and the gate structure includes first, second, and third gate metals with the first gate metal over and around the nanoribbons in the first stack, the second gate metal over and around the nanoribbons in the second stack, and the third gate metal around and between the nanoribbons in the first stack, between the first and second stacks, in contact with both the first and second gate metals, and extending beyond the first metal over the substrate. The first gate metal may act as a temple for selective deposition of the third gate metal. The second gate metal may be conformally deposited over the nanoribbons in the second stack and on the third gate metal.

### BACKGROUND

As gate-all-around (GAA) transistors are continuously scaled, gate geometries shrink, and there is less space available for work-function (WF) metals to set differing threshold voltages (Vₜ) in n- and p-type transistors. As gate geometries shrink, constraints for gate material patterning are introduced, which may require increases in patterning precisions to prevent reliability issues and/or excessive process variabilities. For example, in many existing GAA dual-metal gate patterning schemes, an n- or p-WF metal is first deposited and then patterned, removing some of the n- or p-WF metal, before a second, complementary p- or n-WF metal is then blanket deposited. Such patterning schemes are impaired by multiple challenges. For example, a WF metal deposited after a first WF metal is patterned may “shine through” the first, patterned WF metal, e.g., inadvertently affecting the Vₜ, if the second-deposited WF metal is deposited too closely to the active gate or in excessive quantities, or if too much of the first, patterned WF metal is removed. Patterning may also degrade (e.g., oxidize) a retained WF metal, which may result in an undesired Vₜ shift. Since metal gates are used to exert strain (e.g., to optimize channel conductivities), insufficiently precise patterning (and the consequent removal of too much or not enough gate material) may also result in a loss of strain induced on transistor channels. These patterning issues, collectively or individually, may have the effect(s) of unfavorable (e.g., too high) Vₜ, limited performance, and process and end-product non-uniformities, which consequently may increase defects and reduce both reliability and yields.

New techniques, structures, and materials are needed to improve metal gates in complementary GAA transistors.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A, 1B, 1C, 1D, and 1E illustrate cross-sectional profile views of an integrated circuit (IC) device having a work-function (WF) gate metal on and around a template gate metal over and between a first stack of nanoribbons, and a conformal WF gate metal over and between a second stack of nanoribbons and conformally on a sidewall of the templated WF metal between the first and second stacks, in accordance with some embodiments;

FIGS. 2A, 2B, and 2C illustrate cross-sectional profile views of an IC device having a WF gate metal on and around a template gate metal over and between a first stack of nanoribbons, and a conformal gate metal over and between a second stack of nanoribbons and conformally on a sidewall of the WF gate metal between the first and second stacks, in accordance with some embodiments;

FIG. 3 is a flow chart of methods for forming a gate structure shared by complementary transistor structures and having a template gate metal, a gate metal selectively deposited on the template, and a gate metal conformally on the selectively deposited gate metal, in accordance with some embodiments;

FIGS. 4, 5, 6, 7, 8, 9, 10, 11, 12, and 13 illustrate cross-sectional profile views of an IC device having a gate structure with a first WF metal selectively deposited on a template material over a first transistor channel region and a second WF metal over a second transistor channel region and conformally on the first WF metal, at various stages of manufacture, in accordance with some embodiments;

FIG. 14 illustrates a diagram of an example data server machine employing an IC device having a first WF gate metal selectively deposited on a template gate metal and a second WF gate metal conformally deposited on the first WF gate metal, in accordance with some embodiments; and

FIG. 15 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause-and-effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve integrated circuit (IC) devices having complementary gate-all-around (GAA) transistors, for example, by improving the performance and reliability of dual-metal gates in complementary metal-oxide semiconductor (MOS) field-effect transistors (FET).

The present disclosure describes a dual-metal gate using a template material over a first transistor channel of a first conductivity type (e.g., n- or p-type) and a first work-function (WF) gate metal that deposits selectively on the template material to set the corresponding first threshold voltage (Vₜ). A second WF gate metal (e.g., of opposite or complementary polarity) may then be conformally deposited over a second transistor channel of a second conductivity type (e.g., p- or n-type, complementary to the first conductivity type) to set a corresponding second Vₜ. Both first and second Vₜ may be set at desired values to optimize device performance and reliability without any patterning-related Vₜ-shifting from degradation of the first and second WF gate metals.

Rather than subtractive methods following a deposition, growth and deposition of the first WF gate metal may be confined by controlling the distribution (e.g., location and span of coverage) of the template material over the first transistor channel. The first WF metal may then be selectively deposited thickly enough to sufficiently affect the first Vₜ and to shield the first transistor channel from the second WF metal over the second transistor channel. (If the first WF metal is not thick enough, e.g., a few nanometers, the second WF metal may “shine through” the first WF metal and shift the first Vₜ in the undesired direction.) Blocking structures (such as sacrificial layers) may also be used to confine the selective deposition of the first WF gate metal. The first Vₜ may be set by deployment of a proper first WF metal (e.g., having an appropriate WF) and to a proper thickness (since the size and shape of the volume of a WF metal around a transistor channel affects the Vₜ). A template material may be chosen to have a desired WF, but the template material may be deposited over the first transistor channel sufficiently thinly so as to have minimal effect on the first Vₜ (e.g., relative to the effect of the first WF metal). The first WF metal may be conformally and selectively deposited over the template material sufficiently thickly, e.g., to merge between (and to prevent shine-through by the second WF metal to) first nanoribbon transistor channels.

The second WF gate metal may be conformally deposited over a second transistor channel (e.g., a second stack of nanoribbons) and to an appropriate thickness to set a complementary second Vₜ. The second WF metal may be deposited thickly enough to sufficiently affect the second Vₜ and to shield the second transistor channel from (shine-through by) the first WF metal over the first transistor channel. The conformal deposition of the second WF gate metal may be merged between the second nanoribbons and may also, beyond the second stack of nanoribbons, be on the first WF metal, e.g., on a sidewall of the first WF metal between the first and second stacks of nanoribbons. Both the first and second WF gate metals, in contact between the stacks of nanoribbons, may be deposited thickly enough to prevent shine-through by the other WF metal.

The first WF gate metal may be selectively deposited on the template material in either of an nMOS or pMOS FET, and the second WF gate metal may be conformally deposited in a FET of complementary polarity (e.g., either pMOS or nMOS). The disclosed method reduces the number of required lithographic operations and so reduces the associated costs and process variabilities. Without the eliminated lithography, the disclosed method improves process capability for gate scaling, enabling continued shrinking of device geometries. The first and second WF metals may be used with “volume-less” Vₜ-shifting solutions, e.g., high-permittivity (“high-K”) gate dielectrics with dipole dopants, to enable more-efficient Vₜ-shifting (e.g., more volumetrically efficient) and further device scaling. The disclosed method also reduces the number of operations between depositions of the first and second WF metals, which helps preserve the first WF metal from pattern-based oxidation or other degradation. Without the process variability of subtractive methods, preferred metal deposition methods may also provide improved strain engineering of devices.

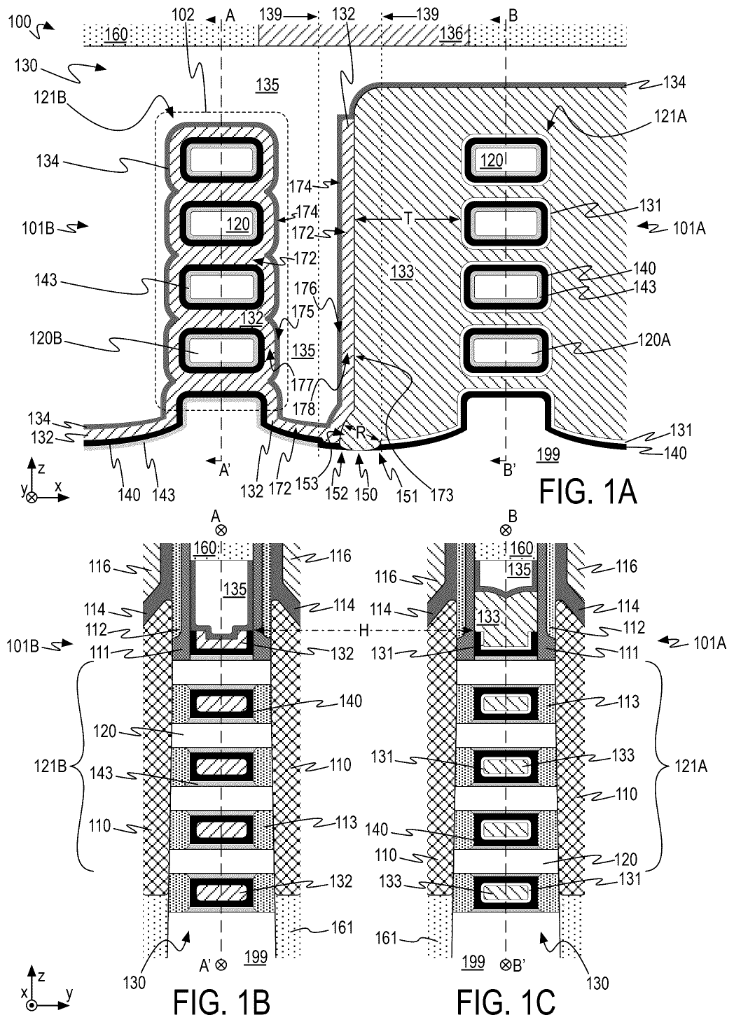

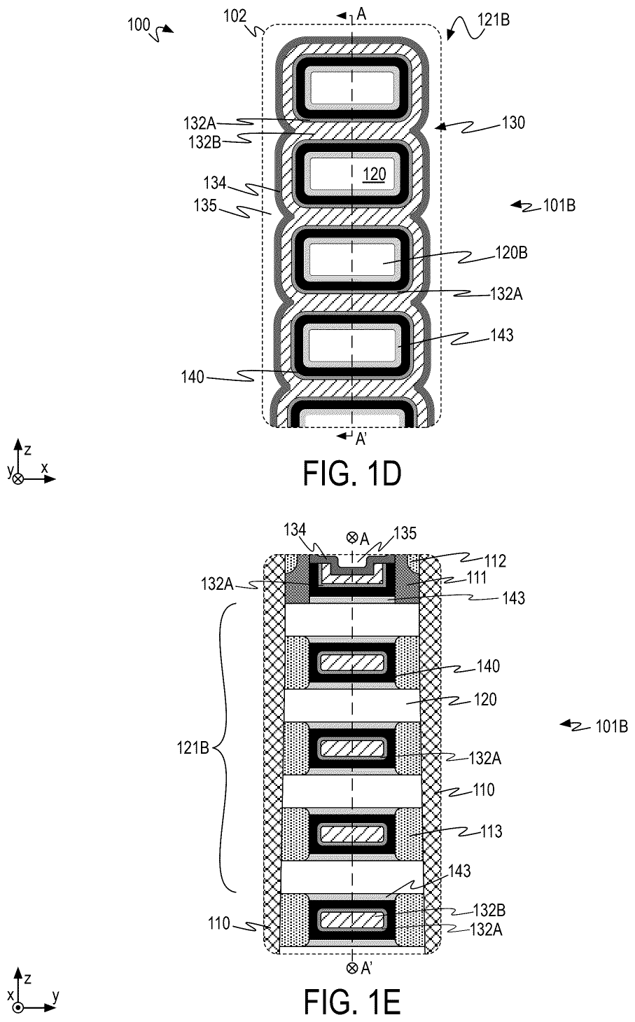

FIGS. 1A, 1B, 1C, 1D, and 1E illustrate cross-sectional profile views of an IC device 100 having a WF gate metal 133 on and around a template gate metal 131 over and between a first stack 121 of nanoribbons 120, and a conformal WF gate metal 132 over and between a second stack 121 of nanoribbons 120 and conformally on a sidewall of the templated WF metal 133 between the first and second stacks 121, in accordance with some embodiments. Gate metal 131 may provide a template for growth of WF gate metal 133, for example, as a seed material for selective deposition of WF metal 133. WF gate metal 132 may be around (and merged between) nanoribbons 120B in second stack 121B and conformally on gate metal 133, which may provide a thickness T between gate metal 131 (and associated nanoribbons 120A in first stack 121A) and WF metal 132. Stacks 121A, 121B of nanoribbons 120A, 120B may be of complementary conductivity types (e.g., of p- and n-type), and metals 131, 132, 133 may be corresponding WF metals in a shared gate structure 130.

FIG. 1A shows the orientations of cross-sections A-A′ and B-B′, which are the viewing planes illustrated by FIGS. 1B and 1C, respectively. FIG. 1A illustrates multiple stacks 121 of nanoribbons 120 extending in the y-directions through the viewing plane and a gate structure 130. FIGS. 1B and 1C show nanoribbons 120 coupling source and drain bodies 110 as channel regions through gate structure 130 in transistor structures 101. FIG. 1A also includes view 102, which is shown in FIG. 1D for an alternate embodiment. Cross-section A-A′ (through view 102) for the alternate embodiment is the viewing plane illustrated by FIG. 1E.

Gate structure 130 includes at least template metal 131, metal 132, and metal 133, which may be WF metals in complementary transistor structures 101A, 101B, e.g., for setting the Vₜ for each transistor structure 101. Metals as described herein are conductive materials, but may include nitrides, carbides, etc., of metal elements. Gate structure 130 is a gate electrode for controlling the conduction of nanoribbon 120 channel regions in transistor structures 101. In some embodiments, transistor structure 101A (with metals 131, 133) is an nMOS FET, and transistor structure 101B (with metal 132) is a pMOS FET. In other embodiments, transistor structure 101A (with metals 131, 133) is a pMOS FET, and transistor structure 101B (with metal 132) is an nMOS FET.

IC device 100 includes gate structure 130 and transistor structures 101A, 101B (which share structure 130) over substrate 199. Each transistor structure 101 includes a stack 121 of nanoribbons 120, for example, nanoribbons 120A in stack 121A and transistor structure 101A and nanoribbons 120B in stack 121B and transistor structure 101B. Nanoribbons 120 are channel regions extending through structure 130 and coupling source and drain regions in front of and behind the viewing plane of FIG. 1A (e.g., in both y-directions). In many embodiments, nanoribbons 120 in stack 121A are of a conductivity type complementary to the conductivity type of nanoribbons 120 in stack 121B. Nanoribbons 120 may include a p-type semiconductor dopant (e.g., electron acceptors, such as boron) or an n-type semiconductor dopant (e.g., electron donors, such as phosphorus or arsenic). Source and drain regions (not shown in FIG. 1A) coupled by nanoribbons 120 may be doped more heavily than nanoribbons 120 and with a different dopant.

Gate structure 130 is over stacks 121 and includes gate insulators 140. Insulators 140 are on and conformally over nanoribbons 120 and (under stacks 121) substrate 199. Transistor structure 101A includes a first gate insulator 140 on nanoribbons 120A and on substrate 199 under stack 121A. Transistor structure 101B includes a second gate insulator 140 on nanoribbons 120B and on substrate 199 under stack 121B. Gate insulator 140 on nanoribbons 120A and over substrate 199 is separated from gate insulator 140 on nanoribbons 120B and on substrate 199 by a discontinuity or gap 150 between insulators 140. Gate insulators 140 over nanoribbons 120A, 120B may have the same or different compositions.

Gate structure 130 and transistor structure 101A both include metal 131 around and between nanoribbons 120A. Template metal 131 is on first gate insulator 140, both over nanoribbons 120A and over substrate 199 under stack 121A.

Gate structure 130 and transistor structure 101B both include metal 132 around and between nanoribbons 120B. WF metal 132 is on second gate insulator 140, both over nanoribbons 120B and over substrate 199 under stack 121B.

Gate structure 130 and transistor structure 101A include metal 133 around and between nanoribbons 120A. WF metal 133 is over template metal 131, over substrate 199, and between substrate 199 and stack 121A of nanoribbons 120A. Seed metal 131 is between metal 133 and substrate 199.

Gate structure 130 includes WF metal 133 between stacks 121A, 121B and in contact with both metals 131, 132. WF metal 132 contacts metal 133 in boundary region 139 (delineated by dotted lines) between stacks 121A, 121B of transistor structures 101A, 101B. WF metal 133 is between metals 131, 132 such that metal 132 is separate from metal 131. In some embodiments, as in the example of FIG. 1A, metal 132 is not over stack 121A. WF metal 132 is separated from metal 131 (and metal 131 is separated from metal 132) by a thickness T of metal 133. WF metal 133 has a thickness T between template metal 131 on first gate insulator 140 over nanoribbons 120A and metal 132 on second gate insulator 140 over nanoribbons 120B. In some embodiments, thickness T is 5 nm or more, which may advantageously provide sufficient barrier between gate metals 131, 132 to prevent excessive influence on the threshold voltage Vₜ of transistor structure 101A by gate metal 132, e.g., without occupying too much space in structures 101A, 130. In some such embodiments, thickness T is 10 nm or more, which may provide increased barrier between gate metals 131, 132 and prevent influence on the threshold voltage Vₜ of transistor structure 101A by gate metal 132.

Metal 131 may be a template or seed metal 131 that enables selective growth of gate metal 133 from (e.g., selective deposition of WF metal 133 on) metal 131. Seed metal 131 may be patterned (e.g., away from nanoribbon 120 channel regions, with an edge in boundary region 139) into a growth template from which metal 133 can grow into the desired gate structure 130. For example, an approximately radial bulge 153 of metal 133 extends from an end of metal 131 on substrate 199 and in boundary region 139, e.g., from a template of seed metal 131. Bulge 153 of metal 133 is in boundary region 139 and extends outwardly (e.g., as if grown) from metal 131 (e.g., up from substrate 199 and towards metal 132 and stack 121B) to approximately an equal distance or radius R from metal 131 under stack 121A. (Although not shown to scale in FIG. 1A, thickness T (of metal 133 between metals 131, 132) and radius R (from an end of metal 131 over substrate 199 to an edge or sidewall of metal 133) are approximately equal in many embodiments.) The employment of metal 131 as a growth template allows the additive control, for example, by confining growth, of metal 133 without the use of subtractive etches, which may cause degradation (e.g., oxidation, etc.) of WF metal and result in unpredictable process variation (e.g., less than desired Vₜ shifting). Any exposure of metal 131 to patterning (e.g., etching) may be sufficiently distant from nanoribbon 120 channel regions of transistor structure 101A (e.g., in boundary region 139) to not affect the Vₜ of transistor structure 101A. Similarly, any exposure of metals 132, 133 to patterning may be sufficiently distant from nanoribbon 120 channel regions (e.g., recessed down on sidewalls, still well above nanoribbons 120) of transistor structures 101B, 101A, respectively, to not affect the Vₜ of transistor structures 101B, 101A (as will be described further, e.g., at FIG. 1B).

Besides patterning template metal 131, blocking layers (or other structures) may be deployed to confine or constrain the selective growth of metal 133 without the necessity of patterning (e.g., subtractively etching) metal 133. Blocking structures, for example, layers of insulator 140 beyond template metal 131, may confine growth of metal 133 to the template of metal 131. (Other blocking structures may be sacrificial and may be removed and not retained in the final device 100.) Metal 133 may extend and grow just beyond, e.g., merging around or onto adjacent structures if the selective deposition of WF metal 133 is sufficiently thick on and over template metal 131. As in the example of bulge 153, metal 133 will be observed to grow out from template metal 131 and merge onto, partially cover, or encapsulate boundary region 139. Such controlled and confined growth of metal 133 (e.g., bulge 153) over stack 121A is in contrast with retained artifacts of subtractive removal methods after a blanket deposition of a WF metal, which may leave stair-step structures at interfaces of WF metals (e.g., a stair-step for each etch removal of a deposited WF metal).

Bulge 153 of metal 133 is on substrate 199 between first and second stacks 121A, 121B, in boundary region 139. WF metal 133 contacts substrate 199 in gap 150 between first and second insulators 140, which may serve as blocking layers. In some embodiments, first gate insulator 140 at a first edge 151 of gap 150 has a same composition as second gate insulator 140 at a second edge 152 of gap 150. In some embodiments, first and second insulators 140 were portions of a continuous layer of insulator 140 over substrate 199 now interrupted by bulge 153 of metal 133 in break or gap 150 between first and second insulators 140.

WF metal 133 may also grow selectively in stack 121A from a template of seed metal 131. Gate metal 131 is on first gate insulator 140 over separate and individual nanoribbons 120A, and metal 133 is conformally on metal 131, around and between nanoribbons 120A, and around and between metal 131 on each nanoribbon 120A. Template metal 131 is on first gate insulator 140 over substrate 199 under stack 121A, and metal 133 is conformally on metal 131 on first gate insulator 140 over substrate 199. WF metal 133 extends beyond metal 131, over substrate 199, and contacts first gate insulator 140 over substrate 199, beyond gate metal 131.

Any suitable materials may be employed as a template metal 131. In many embodiments, metal 131 includes titanium (Ti). In many embodiments, metal 131 includes nitrogen, e.g., in TiN. As in the example of TiN, metal 131 may be a conductive material (e.g., metal or ceramic) that may advantageously be deposited in a thin, conformal film by a well-controlled process and to a well-controlled thickness, for example, by chemical vapor deposition (CVD). A well-controlled thickness of metal 131 may beneficially allow for the consequent control of Vₜ by modulating the influence of metal 133 on Vₜ. In some embodiments, metal 131 is a WF metal 131 with beneficial effect on the Vₜ of transistor structure 101A. In some embodiments, metal 131 has only a slight or negligible effect on the Vₜ of transistor structure 101A, e.g., due to a minimal thickness of metal 131. Template metal 131 may utilize metal-based or metal-nitride-based elements or alloys, for example, Mo, V, Ta, Nb, Mn, Ni, etc., with or without nitrogen.

Any suitable materials may be employed as WF metal 133 over template metal 131. In many embodiments including a pMOS transistor structure 101A, metal 133 includes tungsten (W). In some such embodiments, metal 133 includes nitrogen, e.g., in a nitride of tungsten. In a pMOS transistor structure 101A, gate metal 133 may utilize other metal-based or metal-nitride-based elements or alloys, for example, including Mo, V, Ta, Nb, Mn, Ni, etc., with or without nitrogen. In many embodiments including an nMOS transistor structure 101A, metal 133 includes aluminum (Al). In an nMOS transistor structure 101A, metal 133 may utilize other metal-based or metal-nitride-based elements or alloys, for example, including Hf, Zr, Ti, Ta, AlC, AlCN, Mn, etc. Metal 133 is a conductive material (e.g., metal or ceramic) that may advantageously be selectively deposited (for example, by CVD) over template metal 131, following the exact contour of the metal 131 template (e.g., of TiN) and merging between and around nanoribbons 120. Whether pMOS or nMOS, WF metal 133 beneficially has an effect on Vₜ of structure 101A, “shining through” the thin layer of metal 131.

WF metal 132 is conformally on a sidewall 173 of WF metal 133 in boundary region 139. In many embodiments, metal 132 is conformally deposited on second gate insulator 140 (e.g., on nanoribbons 120B and substrate 199) and on metal 133 over stack 121A. Gate metal 132 is on second gate insulator 140, conformally around and between nanoribbons 120B. Metal 132 is merged between each of nanoribbons 120B, making metal 132 continuous (e.g., an uninterrupted layer) around nanoribbons 120B, on substrate 199, and on sidewall 173 of metal 133. A continuous portion 172 of gate metal 132 is conformally on second gate insulator 140 over and around nanoribbons 120B, is conformally on second gate insulator 140 over substrate 199, and is conformally on sidewall 173 of gate metal 133.

Any suitable materials may be employed as WF metal 132. In many embodiments including an nMOS transistor structure 101B, metal 132 includes titanium, aluminum, and carbon (e.g., in TiAlC). In some nMOS embodiments, metal 132 includes nitrogen or carbon, e.g., in a nitride or carbide of one or more metals. In an nMOS transistor structure 101B, WF metal 132 may utilize metal-based or metal-nitride-based or metal-carbide-based elements or alloys, for example, including Hf, Zr, Ti, Ta, Al, TaAlC, TaAlN, TiAlN, HfAlC, HfAlN, etc. In many embodiments including a pMOS transistor structure 101B, metal 132 includes Ti. In a pMOS transistor structure 101B, gate metal 132 may utilize other metal-based or metal-nitride-based or metal-carbide-based elements or alloys, for example, including W, WN, WCN, Mo, MON, MoCN, Ta, TaCN, TaN, V, VN, VCN, etc. Metal 132 is a conductive material (e.g., metal or ceramic) that may advantageously be conformally deposited (for example, by CVD) over nanoribbons 120B and on a sidewall 173 of WF metal 133, following the exact contour of, and merging between and around, nanoribbons 120B. Whether pMOS or nMOS, WF metal 132 beneficially has an effect on Vₜ of structure 101B.

Gate insulators 140 may include any number of material layers and may have any suitable thickness. In many embodiments, insulator 140 includes an optional interface layer (e.g., of a native or thermal oxide) over nanoribbons 120, between nanoribbons 120 and a high-K material. The oxide may be present only on interfaces with nanoribbons 120. In some embodiments where nanoribbons 120 are substantially pure silicon, the oxide layer includes predominantly silicon and oxygen. An interfacial oxide may have any thickness, but in some examples is at least 1.0 nm. Gate insulators 140 may therefore be a stack of both an interfacial oxide and a high-K material.

First and second gate insulators 140 (in first and second transistor structures 101A, 101B) may have a high-K material of substantially the same chemical composition. The high-K material composition(s) may be any known to be suitable for a transistor gate insulator and that has a bulk relative permittivity greater than 7. One exemplary high-K material has a composition of M1Ox where M1 is a transition or rare earth metal. Examples include a metal oxide including predominantly hafnium (e.g., HfO), a metal oxide including predominantly aluminum (e.g., AlO), a metal oxide including predominantly magnesium (e.g., MgO), a metal oxide including predominantly lanthanum (e.g., LaO), or a metal oxide including predominantly zirconium (e.g., ZrO). In other examples, the high-K material is an alloyed metal oxide including primarily two or more metals (e.g., HfAIO, HfZrO, HfZrLaO). In some further embodiments, the high-K material further includes silicon. For example, metal silicates, such as, but not limited to HfSiO, or ZrSiO, may also be suitable a high-K material for insulators 140.

While both gate insulators 140 may include the same interfacial oxide and same high-K material, the two gate insulators 140 may differ compositionally at least in the presence (or not) or amount (e.g., concentration) of an included Vₜ-shifting dipole dopant 143. A Vₜ-shifting dipole dopant 143 may be deployed with WF metals 131, 132, 133, e.g., in a Vₜ scheme providing multiple available values in a Vₜ range. In exemplary embodiments, one or more Vₜ-shifting dipoles include a metal M2 and may advantageously be an oxide of a rare earth metal that is distinct from any other metal present in gate insulators 140. The chemical compositions of gate insulators 140 may therefore be different by at least the amount (concentration) of this dipole dopant 143 metal species. For example, in embodiments having a pMOS transistor structure 101A and an nMOS transistor structure 101B, N-dipole lanthanum (La) may be present only in insulator 140 in structure 101B to reduce an n-Vₜ magnitude (or only in insulator 140 in structure 101A to increase a p-Vₜ magnitude). In other embodiments with pMOS structure 101A and nMOS structure 101B, a dipole dopant 143 may be present in both insulators 140, and concentrations may be shifted in opposite directions to shift both Vₜ in the same direction (e.g., to improve device time response or leakage current).

While many embodiments may deploy a single dipole dopant 143, (e.g., in different concentrations in complementary transistor structures 101A, 101B), in some embodiments, first and second gate insulators 140 each include a different dipole dopant 143. For example, an N-dipole dopant 143 may reduce an n-Vₜ magnitude in structure 101B and a P-dipole dopant 143 may increase a p-Vₜ magnitude in structure 101A, or vice versa.

Within a given (e.g., first or second) gate insulator 140, the composition of insulator 140 may be substantially constant, for example, across a given transistor structure 101A or 101B, but dipole dopant 143 may be absent (or present, but at a lower concentration) in or adjacent boundary region 139. For example, gate insulators 140 may include different dipole dopants 143 adjacent respective nanoribbons 120A, 120B in structures 101A, 101B, but both dipole dopants 143 may be absent in boundary region 139. In some embodiments, first gate insulator 140 at a first edge 151 of gap 150 has a same composition as second gate insulator 140 at a second edge 152 of gap 150 in boundary region 139.

As noted above, dipole dopant 143 metal M2 is substantially absent from one of first or second insulators 140 in some embodiments. However, in other embodiments, dipole dopant 143 metal M2 is present in one of first or second gate insulators 140, but at lower concentration than within the other of first or second gate insulators 140. Whether associated with an N-dipole or P-dipole, the contrasting amounts of dipole dopant 143 metal M2 may be determined through chemical analysis of the first and second gate insulators 140, for example by STEM-EELS (electron energy-loss spectroscopy)/EDS (energy dispersive x-ray spectroscopy), or 2.5D TOF-SIMS (time-of-flight secondary ion mass spec spectroscopy).

Although dipole dopant 143 is illustrated as a separate layer, e.g., between nanoribbons 120 and insulator 140, dipole dopant 143 may be integrated into (and characterized as part of) insulator(s) 140 and at one or more locations (e.g., depths). Within at least insulator 140, an exemplary dipole dopant metal M2 may be present within an interfacial oxide layer, and therefore in very close proximity (e.g., within 1.0 nm) to nanoribbons 120. In some such embodiments, first and second gate insulators 140 have interfacial oxides that differ by the amount of metal M2 present. Dipole dopant 143 metal M2 may be substantially absent from the high-K material or may be present within high-K material in addition to (or instead of) being within interfacial oxide. In some embodiments of gate insulator 140 where dipole dopant 143 metal M2 is present within high-K material, the concentration of dipole dopant 143 metal M2 within the high-K material is less than the concentration of high-K metal M1 within the high-K material. Hence, the high-K material may still be considered primarily M1Ox with some dipole metal M2 present as dipole dopant 143.

Dipole dopant 143 metal M2 may be present within insulator 140 as non-ionic oxide (e.g., M2Ox) or as an ionic oxide. Exemplary ionic oxides may further include silicon (e.g., as a silicate) when dipole dopant metal M2 is within the interfacial oxide, or may further include metal M1 (e.g., as a hafnate) when M2 is within the high-K material (e.g., HfO). The dipole metal M2 may be any metal that forms a stable dipole compound, including metals known to be suitable as high-K dielectric materials as well as metals that form compounds having somewhat lower dielectric constants. For example, any of the metals listed above as suitable choices for the high-K material may also be suitable as dipole dopant metal M2. Dipole dopant metal M2 may be selected based on dipole properties of compounds it forms within the interfacial oxide and/or high-K material to achieve a particular transistor threshold voltage modulation for a given transistor conductivity type. Suitable examples of N-dipole dopant 143 metal M2 include Mg, Ca, Sr, Ba, La, Sc, Y, Gd, Er, Yb, or Lu (e.g., forming a dipole species M2Ox, M2SiO, M2HfO, etc.). Suitable examples of P-dipole dopant 143 metal M2 include Al, Ga, Mo, Co, Ni, or Nb (e.g., forming a dipole species M2Ox, M2SiO, M2HfO, etc.). Other dipole dopants 143 may be utilized.

Boundary region 139 is between nMOS and pMOS stacks 121 of nanoribbons 120 and is defined by ends or edges of patterned (or otherwise terminated) materials or structures (e.g., insulators 140, dipole dopants 143, template metal 131, etc.). For example, region 139 may be defined by the widest of the ends or edges of the materials or structures in or adjacent (but terminated between) stacks 121 and including all of the ends or edges of the terminated materials or structures. For example, in FIG. 1A, boundary region 139 extends at least from the end of dipole dopant 143 in insulator 140 of transistor structure 101B to the end of template metal 131 in transistor structure 101A. Boundary region 139 includes bulge 153 of metal 133, the ends of insulators 140 and gap 150 between insulators 140, and the interface between metals 132, 133 at sidewall 173.

In many embodiments, gate structure 130 includes further metals. In the example of FIG. 1A, gate structure 130 includes at least a liner metal 134 and a fill metal 135 over or within metal 134. Liner metal 134 is over both stacks 121, e.g., conformal over metals 132, 133. Fill metal 135 is over metal 134 and, in some locations, conformally on metal 134 and between stacks 121. For example, metals 134, 135 are between sectors 177, 178 of a continuous portion 172 of WF metal 132 between stacks 121. A continuous layer 174 of liner metal 134 is conformally on continuous portion 172. Sectors 175, 176 of continuous layer 174 are on portion 172 of metal 132 between stacks 121. Sector 175 of metal 134 layer 174 is on sector 177 of metal 132 portion 172. Sector 176 of metal 134 layer 174 is on sector 178 of metal 132 portion 172. Fill metal 135 is laterally within (or surrounded by) liner metal 134, between sectors 175, 176. In many embodiments, liner metal 134 includes titanium and nitrogen (e.g., in a nitride of titanium, such as TiN). In many embodiments, fill metal 135 includes tungsten. In some embodiments, liner and fill metals 134, 135 are a single material, such as tungsten, integrated into a unified body. In some embodiments, liner and fill metals 134, 135 include other metal-based, metal-nitride-based, and/or metal-carbide-based elements or alloys or combinations, such as WN, WCN, Mo, MON, MoCN, Ta, TaCN, TaN, V, VN, VCN.

An insulator 160, for example, a layer of dielectric, may be over structures 101, 130. In many embodiments, a via or contact 136 may couple gate structure 130, e.g., with one or more interconnect layers (not shown) in an interconnect network (not shown) over structures 101, 130.

Substrate 199 may include any suitable material or materials. In some examples, substrate 199 may include monocrystalline silicon (including silicon on insulator (SOI)), polycrystalline silicon, germanium, silicon germanium, a III-V alloy material (e.g., gallium arsenide), a silicon carbide (e.g., SiC), a sapphire (e.g., Al₂O₃), or any combination thereof. Substrate 199 may refer specifically to a base material (for example, a thick base or layer of semiconductor material) that other materials (such as metals and dielectrics) are built up on. In some contexts, substrate 199 may refer to a base material layer and/or any build-up layers, etc., over or under the base or transistor structures 101. In many embodiments, substrate 199 includes a semiconductor material under nanoribbons 120 (e.g., in a subfin) and under and between source and drain bodies 110 (e.g., of impurity-doped semiconductor material), and nanoribbons 120 are of the same semiconductor material as substrate 199. Substrate 199 may also include other semiconductor materials, metals, dielectrics, dopants, and other materials commonly found in semiconductor substrates.

FIGS. 1B and 1C illustrate nanoribbons 120 as channel regions through gate structure 130, coupling source and drain bodies 110 in transistor structures 101. Metallization structures 114, 116 couple bodies 110 with one or more interconnect layers (not shown) in an interconnect network (not shown) over bodies 110 and structures 101. Spacers 111, 112, 113 are insulators between gate structure 130 and bodies 110. Gate insulators 140 (including dipole dopants 143) are conformally between spacers 113 and nanoribbons 120. Insulators 160 are over gate structures 130, for example, on metals 134, 135. Bodies 110 may be over and/or between insulators 161, e.g., in trenches between structures 130. Spacers 111, 112 are between metals 134, 135 and metallization structures 114, 116.

FIG. 1B shows transistor structure 101B, including stack 121B of nanoribbons 120B. Metal 132 is conformally within gate insulator 140. A top of metal 132 may be recessed, e.g., etched back to a same height H with insulator 140 (and metal 131 in transistor structure 101A and FIG. 1C), but any such etching is over an uppermost nanoribbon 120B and well away from the channel region(s) of nanoribbons 120B, which may preserve a tuned Vₜ of transistor structure 101B. Liner metal 134 (e.g., of a nitride, such as TiN) with fill metal 135 (e.g., of tungsten) may provide a strain in the y-directions, which may improve conductivity of nanoribbons 120B.

FIG. 1C illustrates transistor structure 101A, including stack 121A of nanoribbons 120A. Metal 133 is conformally on and within template metal 131, which is conformally on and within gate insulator 140 between nanoribbons 120A. Metal 133 (e.g., of tungsten in a pMOS structure 101A, or of aluminum in an nMOS structure 101A) is in contact with spacer 111 and gate insulator 140 over stack 121A, e.g., where metal 133 was selectively deposited on template metal 131 (e.g., of TiN). A top of metal 131 may be recessed, e.g., etched back to a same height H with insulator 140 (and metal 132 in transistor structure 101B and FIG. 1B), but any such etching is over and well away from nanoribbons 120A, which may preserve a tuned Vₜ of transistor structure 101A. Liner metal 134 (e.g., of a nitride, such as TiN) with fill metal 135 (e.g., of tungsten) may provide a strain in the y-directions, which may improve conductivity of nanoribbons 120A.

FIGS. 1D and 1E illustrate orthogonal cross-sectional views of one or more alternate embodiments of transistor structure 101B. FIG. 1D shows x-z view 102 (e.g., somewhat magnified from view 102 of FIG. 1A) of structure 101B (including stack 121B of nanoribbons 120B), but with metal 132 including a stack of conformal metals 132A, 132B. FIG. 1E illustrates orthogonal, y-z cross-sectional view of the embodiment(s). Conformal metal 132A may be a template metal 132A that enables the selective growth of metal 132B on only metal 132A.

In FIG. 1D, metal 132A is conformally on and around gate insulator 140, which is on and around nanoribbons 120B. Metal 132B is conformally on and around metal 132A, and is merged between nanoribbons 120B.

In FIG. 1E, metal 132A is conformally within gate insulator 140 between nanoribbons 120B, and metal 132B is conformally within metal 132A between nanoribbons 120B.

In some embodiments having a pMOS transistor structure 101B, metal 132A includes titanium and nitrogen (e.g., in a nitride of titanium, such as TiN), and metal 132B is or includes tungsten. In other pMOS embodiments of transistor structure 101B, metals 132A, 132B include one or more metal-based, metal-nitride-based, and/or metal-carbide-based elements, alloys, laminates, or combinations, such as W, WN, WCN, Mo, MON, MoCN, Ta, TaCN, TaN, V, VN, VCN, etc. Other materials may be deployed in a stack of metals 132A, 132B.

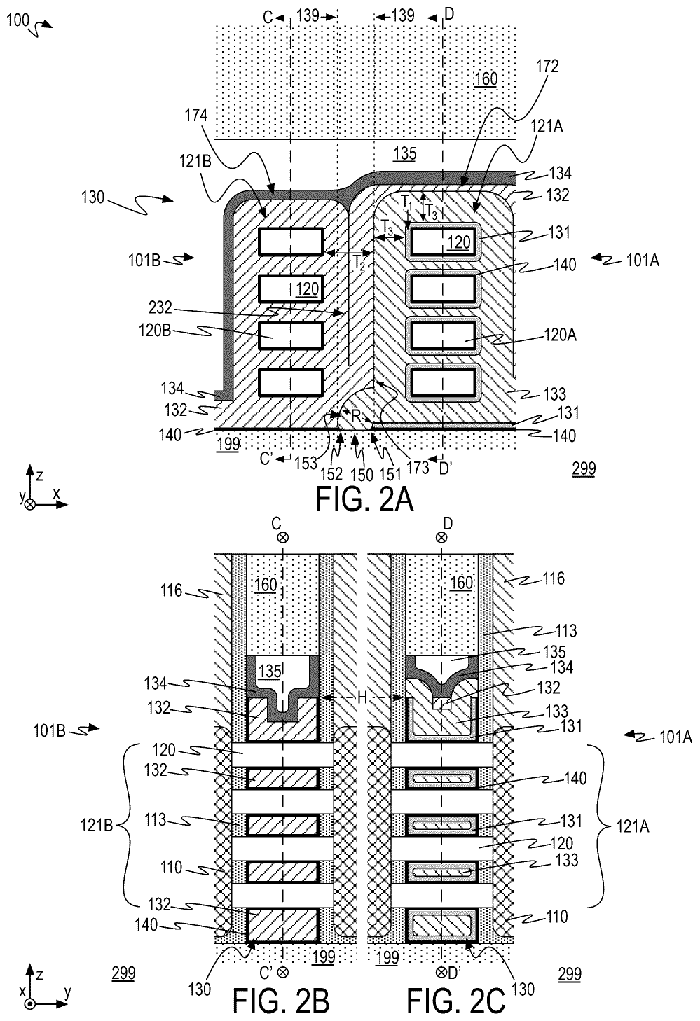

FIGS. 2A, 2B, and 2C illustrate cross-sectional profile views of IC device 100 having a WF gate metal 133 on and around a template gate metal 131 over and between a first stack 121 of nanoribbons 120, and a conformal gate metal 132 over and between a second stack 121 of nanoribbons 120 and conformally on a sidewall of the WF gate metal 133 between the first and second stacks 121, in accordance with some embodiments. FIG. 2A shows the orientations of cross-sections C-C′ and D-D′, which are the viewing planes illustrated by FIGS. 2B and 2C, respectively. The embodiments of FIGS. 2A-2C share similarities with those of FIGS. 1A-1C (e.g., stacks 121A, 121B of nanoribbons 120A, 120B in transistor structures 101A, 101B sharing a gate structure 130), but with notable differences.

In FIG. 2A, as in FIG. 1A, template metal 131 is on gate insulator 140 around and between nanoribbons 120A in transistor structure 101A, and WF metal 133 is on and around (e.g., selectively deposited on) metal 131 between nanoribbons 120A. Gate metal 132 is around (and merged between) nanoribbons 120B in second stack 121B and conformally on gate metal 133, which provides a thickness T₃ between gate metal 131 and gate metal 132. Stacks 121A, 121B of nanoribbons 120A, 120B may be of complementary conductivity types, and metals 131, 132, 133 may be WF metals in shared gate structure 130.

Notably, gate metal 132 is deposited to a sufficient thickness to merge between stacks 121A, 121B, e.g., at seam 232. WF metal 132 of sufficient thickness between stacks 121 to merge may provide increased influence (e.g., shielding, preventing shine-through by WF metal 133) on a Vₜ of transistor structure 101B. Metal 132 is over metal 133 and stack 121A. Metals 134, 135 are over metal 132 over both stacks 121. Metals 134, 135 are not between stacks 121, e.g., not below a top of uppermost nanoribbons 120A, 120B.

Stacks 121A, 121B (and corresponding gate insulators 140) are separated by a sum of thicknesses T₁, T₂, T₃ of metals 131, 132, 133, respectively, e.g., without a thickness of fourth or fifth metals 134, 135. Template metal 131 has a consistent thickness T₁ (and is conformal) around nanoribbons 120A. Metal 133 has a consistent thickness T₃ from template metal 131, e.g., as grown with an even growth rate from template metal 131, around nanoribbons 120A and over substrate 199. Thickness T₃ of metal 133 separates template metal 131 from WF metal 132 over stack 121A and between stacks 121A, 121B. Merged thickness T₂ is between WF metal 133 and gate insulator 140 of stack 121B.

N/P boundary region 139 includes sidewall 173 of metal 133, e.g. where metals 132, 133 abut. Region 139 includes bulge 153 of metal 133. Bulge 153 extends to radius R from template metal 131. Bulge 153 of metal 133 contacts substrate 199 and both insulators 140 in gap 150. Radius R is approximately equal to thickness T₃, e.g., a consistent distance of growth (for example, selective deposition) of metal 133 from template metal 131. Edges 151, 152 of insulators 140 and gap 150 are included in region 139.

Continuous portion 172 of gate metal 132 is conformally on WF metal 133 over first stack 121A. Gate structure 130 includes fourth and fifth metals 134, 135 over first and second stacks 121A, 121B. Continuous layer 174 of fourth metal 134 is over first and second stacks 121A, 121B. Fifth metal 135 is over fourth metal 134. Continuous portion 172 of WF metal 132 is between third and fourth metals 133, 134.

Substrate 199 may include any suitable material or materials. In many embodiments, substrate 199 includes the material of nanoribbons 120 (e.g., silicon). In many embodiments, substrate 199 includes other materials, such as dielectrics in build-up layers over or under transistor structures 101.

IC device 100 (and structures 101) may be coupled to one or more power supplies on or through a host component 299 coupled to substrate 199. Host component 299 is a planar platform or substrate and may include dielectric and metallization structures. Host component 299 may mechanically support, and electrically couple to, substrate 199. At least one side of host component 299 includes interconnect interfaces, e.g., for soldering or direct bonding to one or more IC dies or other substrates. The opposite side of host component 299 may include similar interfaces or, e.g., copper pads for socketing or solder bumps for bonding to another substrate or host component, for example, a printed circuit board. Host component 299 may be any platform with interconnect interfaces, such as a package substrate or interposer, another IC die, etc. Host component 299 may itself be a die or an insulating substrate. Host component 299 may bond to any platform, such as a package substrate or interposer, another IC die, etc. In many embodiments, substrate 199 is an IC die, and host component 299 is a package substrate or interposer.

FIG. 2B shows transistor structure 101B, including stack 121B of nanoribbons 120B. Metal 132 is conformally within gate insulator 140. A top of metal 132 may be recessed over both stacks 121A, 121B to a same height H with insulator 140 (and metal 131 in transistor structure 101A and FIG. 2C), but any recessing is over an uppermost nanoribbon 120B and well away from the channel region(s) of nanoribbons 120B, which may preserve a tuned Vₜ of transistor structure 101B. Liner metal 134 (e.g., of a nitride, such as TiN) with fill metal 135 (e.g., of tungsten) may provide a strain in the y-directions, which may improve conductivity of nanoribbons 120B.

FIG. 2C illustrates transistor structure 101A, including stack 121A of nanoribbons 120A. Metal 133 is conformally on and within template metal 131, which is conformally on and within gate insulator 140 between nanoribbons 120A. Metal 133 (e.g., of tungsten in a pMOS structure 101A, or of aluminum in an nMOS structure 101A) is in contact with spacer 113 and gate insulator 140 over stack 121A, e.g., where metal 133 was selectively deposited on template metal 131 (e.g., of TiN). A top of metal 131 may be recessed, e.g., etched back to a same height H with insulator 140 (and metal 132 over both stacks 121A, 121B), but any such etching is over and well away from nanoribbons 120A, which may preserve a tuned Vₜ of transistor structure 101A. Liner metal 134 (e.g., of a nitride, such as TiN) with fill metal 135 (e.g., of tungsten) may provide a strain in the y-directions, which may improve conductivity of nanoribbons 120A.

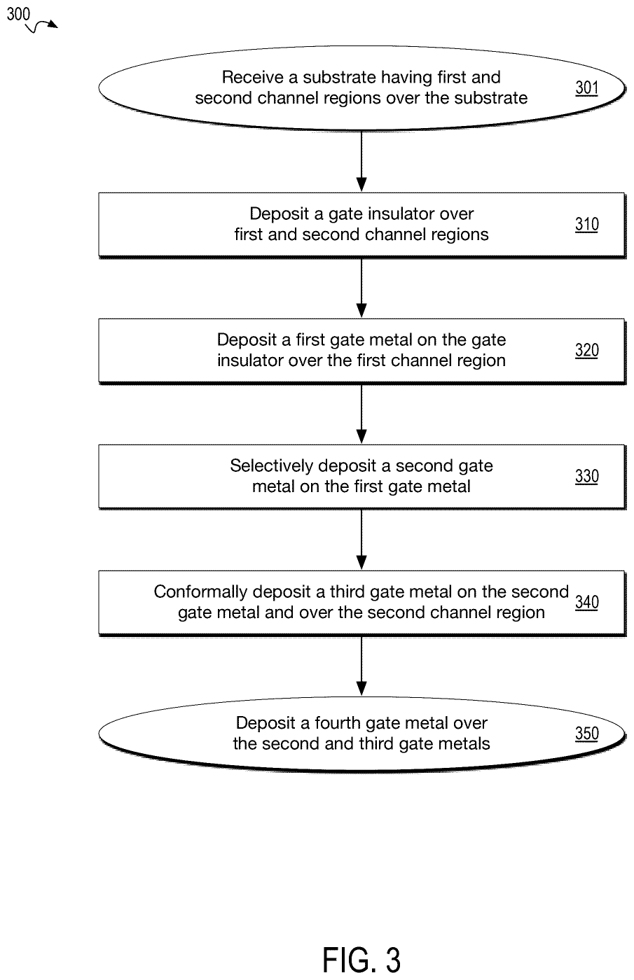

FIG. 3 is a flow chart of methods 300 for forming a gate structure shared by complementary transistor structures and having a template gate metal, a gate metal selectively deposited on the template, and a gate metal conformally on the selectively deposited gate metal, in accordance with some embodiments. Methods 300 include operations 301-350. Some operations shown in FIG. 3 are optional. Additional operations may be included. FIG. 3 shows an example sequence, but the operations can be done in other orders as well, and some operations may be omitted. Some operations can also be performed multiple times before other operations are performed. Some operations may be included within other operations so that the number of operations illustrated FIG. 3 is not a limitation of the methods 300.

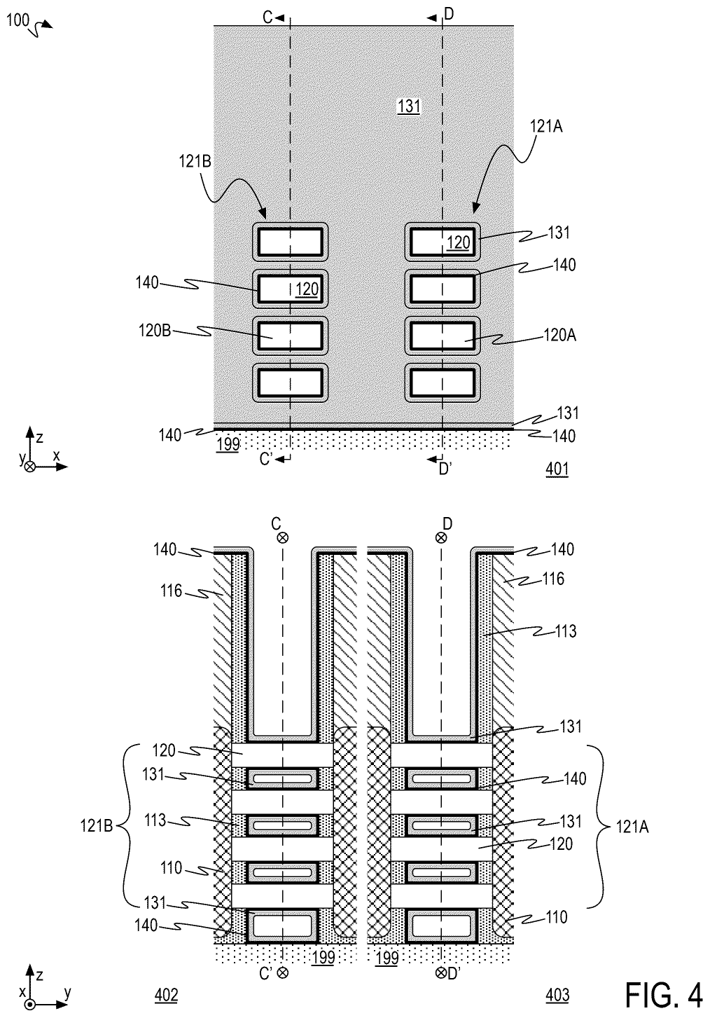

Note that the first gate metal described at FIG. 3 (and at FIGS. 4-13) may be a template material (e.g., similar to metal 131 at FIG. 1A), the second gate metal described at FIG. 3 may be the (first) WF metal on the template material in the same stack or transistor structure (e.g., similar to metal 133 at FIG. 1A), and the third gate metal described at FIG. 3 may be the (second) WF metal over the other stack or in a second, complementary transistor structure (e.g., the same as or similar to metal 132 at FIG. 1A).

FIGS. 4, 5, 6, 7, 8, 9, 10, 11, 12, and 13 illustrate cross-sectional profile views of an IC device having a gate structure with a first WF metal selectively deposited on a template material over a first transistor channel region and a second WF metal over a second transistor channel region and conformally on the first WF metal, at various stages of manufacture, in accordance with some embodiments. FIGS. 4-13 show possible examples of intermediate structures during an embodiment of a practice of methods 300 of FIG. 3. FIGS. 4-13 each include multiple orthogonal views, one of an x-z viewing plane and others with y-z viewing planes. For example, FIG. 4 includes view 401 with an x-z viewing plane and views 402, 403 with y-z viewing planes. Note that some x-z cross-sections are through voids or openings, and some of the illustrated structures are behind (and shown as through) the viewing plane.

Returning to FIG. 3, methods 300 begin at operation 301 with receiving a substrate. In many embodiments, the substrate includes channel regions, e.g., nanoribbons coupling source and drain bodies. The nanoribbons may be in stacks, with each stack including multiple vertically-aligned nanoribbons coupling a pair of source and drain bodies. In many embodiments, the channel regions are in complementary pairs in and over the substrate, e.g., with one stack of nanoribbons having a first conductivity type (e.g., p- or n-type) and an adjacent stack of nanoribbons having a second, complementary conductivity type (e.g., n- or p-type).

The substrate may be much as described elsewhere herein (e.g., at FIG. 1A), for example, including a monocrystalline semiconductor (e.g., silicon) portion with channel regions (e.g., in stacks of silicon nanoribbons) over the semiconductor portion. In some embodiments, the channel regions are over an interconnect section of the substrate having metallization (e.g., lines and vias) through a low-K dielectric. In some such embodiments, the channel regions are over a back-side interconnect section, between front- and back-side interconnect sections, for example, with most or all of an underlying semiconductor portion removed.

Methods 300 continue with depositing a gate insulator at operation 310. The gate insulator may be deposited over one or more channel regions, e.g., both of a pair of stacks of nanoribbons. In many embodiments, the gate insulator is deposited conformally over the substrate and over first and second (e.g., complementary) channel regions, for example, by CVD, an atomic layer deposition (ALD), etc. In some such embodiments, the gate insulator includes one or more layers. In some such embodiments, one or more layers of the one or more layers are each continuous over the first and second channel regions and over the substrate. In many embodiments, the gate insulator is continuous over the substrate under and between the first and second channel regions.

The gate insulator may be deposited by any suitable means, such as CVD, ALD, and/or another deposition process. The gate insulator may include any suitable material(s), which may be deposited in multiple layers and by separate operations. For example, the gate insulator may include a low-K oxide layer deposited conformally over a channel region and a high-K layer deposited conformally over the low-K layer. In many embodiments, one or more dipole dopants are deposited and included within the gate insulator. A dipole dopant may be deposited over the channel region or over any dielectric layer, and the location (e.g., depth relative to the layer(s) in the gate insulator) of the dipole may affect the influence of the dipole on a Vₜ. One or more anneals may be performed after dipole or dielectric deposition to diffuse the dipole into an insulator layer.

In many embodiments, the gate insulator will advantageously act as a blocking layer that prevents (or at least inhibits) growth of a subsequent WF metal on a template metal deposited on and over the gate insulator.

Methods 300 continue at operation 320 with depositing a first gate metal over a first channel region. The first gate metal may be a template material, e.g. that acts as a seed metal for subsequent selective deposition of a WF gate metal on the template of the first gate metal. In many embodiments, the first gate metal is deposited on a gate insulator over a first channel region. In many embodiments, the first gate metal is deposited over both stacks of nanoribbons (e.g., first and second channel regions) in a pair of complementary stacks. In some such embodiments, the first gate metal will be subsequently removed from over the second, complementary channel region. In many embodiments, the depositing the first gate metal on the gate insulator includes depositing the first gate metal on the gate insulator at least over the first channel region and over the substrate under the first channel region. The first gate metal over the substrate under the first channel region may serve as a template for growth of the WF gate metal from the substrate up to merge with growth of the WF gate metal on the gate insulator over the first channel region.

The first gate metal may be deposited by any suitable means, such as CVD, ALD, and/or another deposition process. The first gate metal may be deposited to any suitable thickness, for example, with sufficient adhesion and thickness to properly serve as a seed or template material for subsequent deposition of a WF metal and with a thickness appropriate for the desired Vₜ-shifting scheme (e.g., in combination with a WF metal over the first gate metal). The first gate metal may include any suitable material(s), such as those described of template metal 131 (e.g., at FIG. 1A).

The first gate metal, as a template material for subsequent selective deposition of a WF gate metal, may be utilized to confine the subsequent growth of a WF metal by controlling the distribution (e.g., location and span of coverage) of the first gate metal. In many embodiments, growth of a WF metal from a template first gate metal will be limited to a small distance beyond edges of the first gate metal (e.g., a small distance directly related to a growth rate of the WF gate metal and to the duration of the growth). In many embodiments, the first gate metal is patterned or recessed, for example, before a second gate metal (e.g., a WF metal) is grown from the template of the first gate metal. The patterning or recessing of the first gate metal may reduce the extent of the first gate metal and consequently limit the extent of the second gate metal. The patterning or recessing of the first gate metal may beneficially preclude the need to pattern or recess a subsequently deposited second gate metal (e.g., a WF metal), which may preserve the second gate metal from degradation (e.g., caused by etching).

The first gate metal may be patterned or recessed by any suitable means. In some embodiments, a blocking material is deposited over the first gate metal to be retained, e.g., to a desired height for a recess of the first gate metal, and exposed portions of the first gate metal are removed (e.g., by a wet or dry etch). In many embodiments, a blocking material is deposited over the first gate metal, some of the blocking material is removed (e.g., down to a desired height for a recess of the first gate metal), and exposed portions of the first gate metal are removed (e.g., by a wet or dry etch). In some embodiments, a blocking material is patterned (e.g., deposited and/or removed in lithographically determined areas) over portions of the first gate metal before exposed portions of the first gate metal are removed (e.g., by a wet or dry etch). In many embodiments, a blocking material is conformally deposited over at least portions of the first gate metal before exposed portions of the first gate metal are removed (e.g., by a wet or dry etch). In some such embodiments, a first blocking material is conformally deposited over the first gate metal, a second blocking material is deposited over at least portions of the first blocking material (for example, patterned to cover portions of the first blocking material to be retained and to expose portions of the first blocking material to be removed), exposed portions of the first blocking material are removed (e.g., by a wet or dry etch), and exposed portions of the first gate metal are removed (e.g., by a wet or dry etch). In some such embodiments, portions of the first gate metal are removed from over the second channel region. Multiple blocking materials may be deployed to provide additional etch selectivities, for example, to enable etches of some materials while protecting other materials, such as the first gate metal. The employment of blocking material(s) over the channel regions allows for the etching of the template metal away from the channel regions, which ensures that any gate metal exposed to a removal etch (e.g., at an edge of a masking or blocking material, away from the channel regions) will not be undesirably affected (e.g., degraded in a manner that may in turn undesirably affect a Vₜ). The blocking material(s) may be any suitable material(s), for example, having sufficient etch selectivities with other key materials, e.g., otherwise exposed dielectrics, etc.

FIG. 4 illustrates template metal 131 on gate insulator 140 over stacks 121A, 121B of nanoribbons 120A, 120B in or over substrate 199 in a workpiece or device 100, in accordance with some embodiments, for example, following a performance of receiving operation 301 and depositing operations 310, 320. FIG. 4 includes view 401 with an x-z viewing plane and views 402, 403 with y-z viewing planes. View 401 shows the orientations of cross-sections C-C′ and D-D′, which are the viewing planes illustrated by views 402, 403, respectively. Note that some of the illustrated structures (e.g., metal 131 over and behind nanoribbons 120 in view 401) are behind (and shown through) the x-z viewing plane, which is through openings over, between, and under nanoribbons 120 (e.g., following a removal of a polysilicon dummy gate and a release of nanoribbons 120).

View 401 shows nanoribbons 120 extending in the y-directions, through the x-z viewing plane. Nanoribbons 120A in stack 121A are of a conductivity type complementary to that of nanoribbons 120B in stack 121B. Stacks 121A, 121B are over substrate 199. Gate insulator 140 is conformally on nanoribbons 120A, 120B. Gate insulator 140 is conformally on substrate 199, continuous under nanoribbons 120A, 120B and between stacks 121A, 121B. Although not shown separately from insulator 140, gate insulator 140 may include a dipole dopant, for example, to modulate a Vₜ. A dipole dopant may be embedded evenly through insulator 140 or may be substantially on an interface between surfaces (e.g., between nanoribbons 120 and insulator 140, between insulator 140 and metal 131, or between low- and high-K layers within gate insulator 140). Template metal 131 is conformally on insulator 140, over nanoribbons 120 and substrate 199. Template metal 131 is also behind and seen through the viewing plane, on a sidewall over substrate 199 and under, over, and behind nanoribbons 120.

Views 402, 403 have parallel y-z viewing planes (e.g., offset in the x-direction) and show nanoribbons 120 extending in the y-directions, coupling different pairs of source and drain bodies 110. Nanoribbons 120A in stack 121A are parallel to and aligned (e.g., at a same height or level) with nanoribbons 120B in stack 121B. Insulator 140 and metal 131 are conformally on substrate 199 and nanoribbons 120, as well as conformally on spacer 113 between, over, and under nanoribbons 120. Spacer 113 is on bodies 110 and metallization structures 116 over bodies 110.

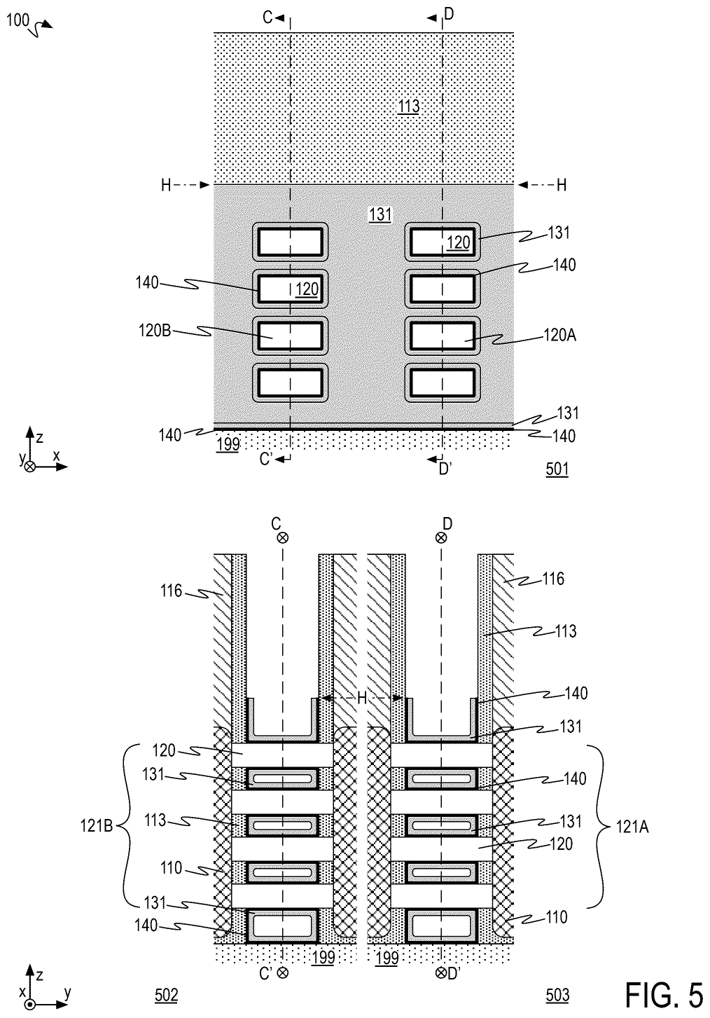

FIG. 5 shows spacer 113 and metal 131 over substrate 199 in a workpiece or device 100, in accordance with some embodiments, for example, following a recessing operation reducing metal 131 to height H on spacer 113. FIG. 5 includes view 501 with an x-z viewing plane and views 502, 503 with y-z viewing planes. View 501 shows the orientations of cross-sections C-C′ and D-D′, which are the viewing planes illustrated by views 502, 503, respectively. Note that some of the illustrated structures (e.g., spacer 113 and metal 131 over and behind nanoribbons 120 in view 501) are behind (and shown through) the x-z viewing plane, which is through openings over, between, and under nanoribbons 120.

View 501 illustrates spacer 113 exposed above height H, and metal 131 is absent above height H. Metal 131 is present below height H, conformally on insulator 140, over nanoribbons 120 and substrate 199. Metal 131 is also behind and seen through the viewing plane, on a sidewall of spacer 113 over substrate 199 and under, over, and behind nanoribbons 120.

Views 502, 503 show gate insulator 140 and metal 131 conformally on substrate 199 and nanoribbons 120, as well as conformally on spacer 113 under height H, between, over, and under nanoribbons 120. Spacer 113 is on bodies 110 and metallization structures 116 over bodies 110. Spacer 113 is covered by metal 131 below height H and is exposed above height H.

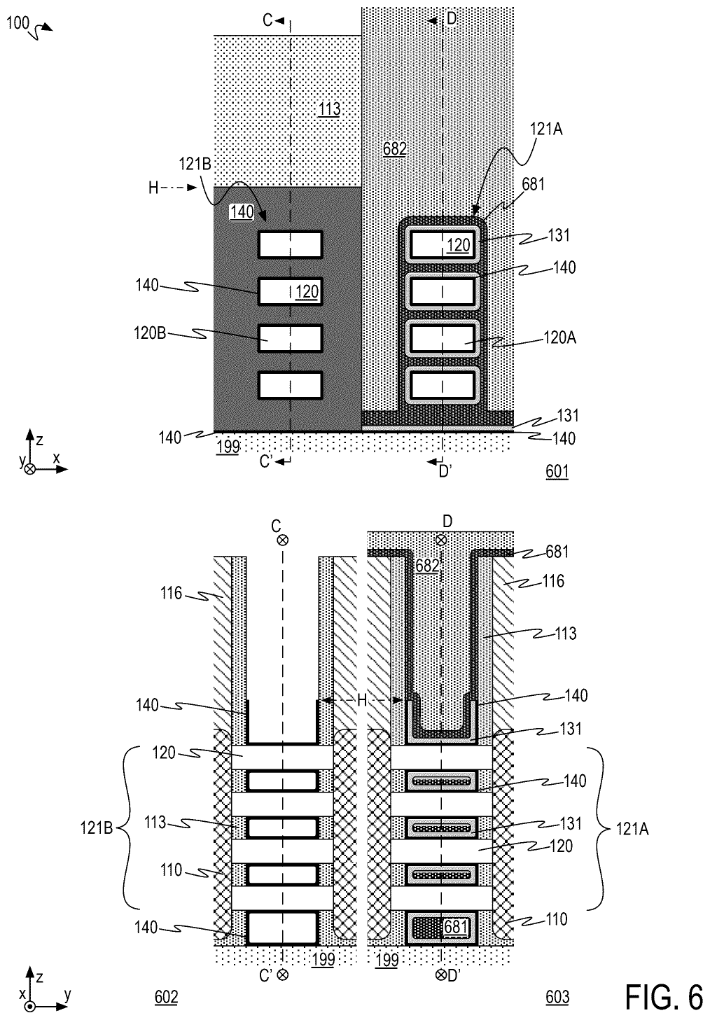

FIG. 6 illustrates spacer 113 and gate insulator 140 over second stack 121B and blocking materials 681, 682 over first stack 121A in a workpiece or device 100, in accordance with some embodiments, for example, following a pattering operation removing metal 131 from over second stack 121B. FIG. 6 includes view 601 with an x-z viewing plane and views 602, 603 with y-z viewing planes. View 601 shows the orientations of cross-sections C-C′ and D-D′, which are the viewing planes illustrated by views 602, 603, respectively. Note that some of the illustrated structures (e.g., spacer 113 and insulator 140 over and behind nanoribbons 120B in view 601) are behind (and shown through) the x-z viewing plane.

View 601 illustrates metal 131 absent over second stack 121B, spacer 113 present and exposed above height H over second stack 121B, and insulator 140 absent above height H. Gate insulator 140 is present over second stack 121B, exposed below height H, and conformally on nanoribbons 120B and substrate 199. Gate insulator 140 is also behind and seen through the viewing plane, on a sidewall over substrate 199 and under, over, and behind nanoribbons 120B.

View 601 shows first stack 121A masked, covered by blocking materials 681, 682. Gate insulator 140 is conformally on nanoribbons 120A and, under stack 121A, substrate 199. Gate metal 131 is conformally on insulator 140, over substrate 199 and around nanoribbons 120A. Blocking material 681 is conformally on metal 131, over stack 121A. Blocking material 682 is conformally on material 681 and over stack 121A, for example, as if patterned to leave stack 121B exposed.

Views 602, 603 illustrate gate insulator 140 exposed and conformally on substrate 199 and nanoribbons 120B under height H, conformally covering spacer 113 below height H. Spacer 113 is on bodies 110 and metallization structures 116 over bodies 110, exposed above height H over stack 121B.

Views 602, 603 show gate insulator 140 on nanoribbons 120A covered by metal 131 below height H. Blocking material 681 is conformally on metal 131 over stack 121A below height H and conformally covering spacer 113 above height H. Blocking material 682 is on, and covering, material 681 and over stack 121A, for example, as if patterned to leave stack 121B exposed.

Returning to FIG. 3, methods 300 continue by depositing a second gate metal at operation 330. The second gate metal may be a WF metal, e.g., employed to shift a Vₜ for a first channel region. The second gate metal may be selectively deposited on the first gate metal, e.g., using the first gate metal as a template to confine growth of the second gate metal. In many embodiments, the selectively depositing the second gate metal on the first gate metal deposits the second gate metal conformally on the first gate metal and conformally on the gate insulator over the substrate beyond the first gate metal. The gate insulator may be a blocking layer that the second gate metal can only grow over as it extends somewhat beyond the edges of the first gate metal template. For example, growth of a WF, second gate metal from a first gate metal template may be limited to a small distance beyond edges of the first gate metal, e.g., a small distance directly related to the rate and duration of the growth of the WF gate metal. In some embodiments, the depositing the second gate metal conformally on the gate insulator deposits the second gate metal on the substrate in a gap in the gate insulator over the substrate and between the first and second channel regions.

The second gate metal may include any suitable material(s), such as those described of WF metal 133 (e.g., at FIG. 1A). The second gate metal may be deposited by any suitable means, such as CVD, ALD, and/or another deposition process. The second gate metal may be deposited to any suitable thickness, for example, to a thickness sufficient to prevent shine-through by a subsequently deposited WF metal of complementary polarity over the second channel region. In some embodiments, the second gate metal is selectively deposited on the first gate metal to a thickness of at least 10 nm, which may be thick enough to completely prevent shine-through of another WF metal (e.g., of opposite or complementary polarity). In some embodiments, the second gate metal is selectively deposited on the first gate metal to a thickness of at least 5 nm, which may be thick enough to sufficiently prevent shine-through of another WF metal (e.g., of opposite or complementary polarity) while minimizing gate volume occupied by the second gate metal (e.g., in a space-constrained gate structure). In many embodiments, a first channel region includes a first stack of nanoribbons with the gate insulator conformally around the nanoribbons and the first gate metal conformally around the gate insulator. In some such embodiments, selectively depositing the second gate metal on the first gate metal deposits the second gate metal conformally around (the gate insulator, the first gate metal and) the nanoribbons, and the second gate metal merges between the nanoribbons, e.g., providing a continuous structure of the second gate metal from over an uppermost of the first nanoribbons to under a lowermost of the first nanoribbons.

Growth of the second gate metal may be controlled by any suitable means. Advantageously, growth or deposition of the second gate metal is confined to the area adjacent the first channel region (e.g., a first stack of nanoribbons) so that subtractive, removal methods are not needed to reduce an extent of the second gate metal. In many embodiments, a blocking material is deposited over the second, complementary channel region (e.g., a second stack of nanoribbons), which may ensure the second gate metal is not selectively deposited over the second channel region (e.g., by blocking or covering over a metal oxide of the gate insulator over the second channel region). The blocking material(s) may be any suitable material(s), for example, having sufficient etch selectivities with other key materials, e.g., otherwise exposed dielectrics, etc.

Multiple blocking materials may be deployed to provide additional etch selectivities, for example, to enable etches of some materials while protecting other materials, such as the second channel region. The employment of some blocking materials over the second channel region may allow for aggressive etching of an upper blocking material before more gently (e.g., selectively and/or isotropically) removing a lower blocking material from the second channel region, which may prevent degradation of retained materials.

In many embodiments, a first blocking material is conformally deposited over at least the second stack of nanoribbons to a thickness sufficient for the first blocking material to merge between the nanoribbons. In some such embodiments, the first blocking material is deposited over both stacks of nanoribbons. In many embodiments, an isotropic etch of a conformal and merged blocking material removes exposed blocking material and retains merged blocking material between the nanoribbons. In some such embodiments, a second blocking material is conformally deposited over the first blocking material. In some such embodiments, a third blocking material is then deposited over the second blocking material and patterned to be retained on the second stack. In some such embodiments, the third blocking material covers the second blocking material on the second stack, but enables removal (for example, by selective etches) of the first and second blocking materials on the first stack of nanoribbons, exposing the template of the first gate metal over the first nanoribbons. The use of separate blocking materials between nanoribbons (e.g., merged portions) and over the nanoribbon stacks may provide a first blocking material with precise conformal thickness control for ensuring merged blocking material between nanoribbons (which prevents inadvertent selective deposition of a second gate metal in a wrong nanoribbon stack) and a second blocking material over the stacks with a superior etch selectivity.

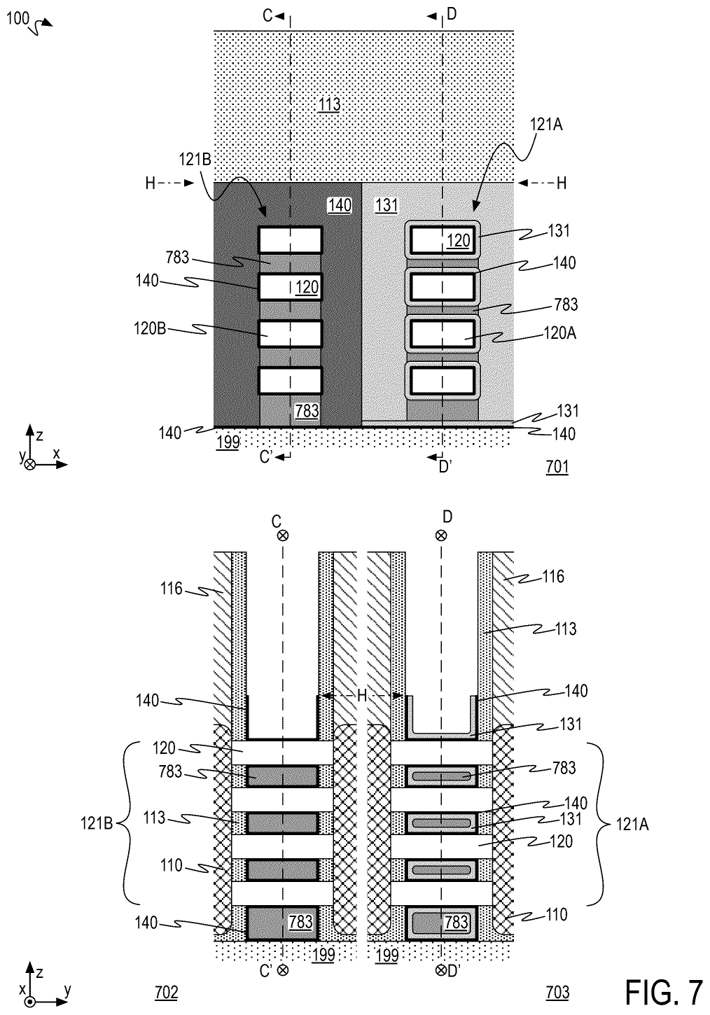

FIG. 7 shows metal 131 exposed on a sidewall adjacent first stack 121A in a workpiece or device 100, in accordance with some embodiments, for example, following operations removing blocking materials 681, 682 from over first stack 121A and depositing blocking material 783 between nanoribbons 120A and between nanoribbons 120B. FIG. 7 includes view 701 with an x-z viewing plane and views 702, 703 with y-z viewing planes. View 701 shows the orientations of cross-sections C-C′ and D-D′, which are the viewing planes illustrated by views 702, 703, respectively. Note that some of the illustrated structures (e.g., metal 131 over and behind nanoribbons 120A, insulator 140 over and behind nanoribbons 120B, and spacer 113, all in view 701) are behind (and shown through) the x-z viewing plane.

View 701 illustrates blocking materials 681, 682 absent over first stack 121A (and second stack 121B). Metal 131 is exposed below height H on a sidewall adjacent first stack 121A. Gate insulator 140 is exposed below height H on a sidewall adjacent second stack 121B. Spacer 113 is exposed above height H over first and second stacks 121A, 121B. Metal 131 and insulator 140 are absent above height H.

View 701 shows blocking material 783 between nanoribbons 120A and between nanoribbons 120B. In many embodiments, blocking material 783 is deposited conformally on nanoribbons 120 thickly enough to merge between nanoribbons 120, exposed portions of blocking material 783 are removed (e.g., selectively and/or isotropically etched), and merged portions between nanoribbons 120 are retained.

Views 702, 703 illustrate blocking materials 681, 682 absent over first stack 121A (and second stack 121B). Metal 131 is exposed below height H on a sidewall adjacent first stack 121A. Gate insulator 140 is exposed below height H on a sidewall adjacent second stack 121B. Spacer 113 is exposed above height H over first and second stacks 121A, 121B. Metal 131 and insulator 140 are absent above height H. Views 702, 703 show blocking material 783 between nanoribbons 120A and between nanoribbons 120B.

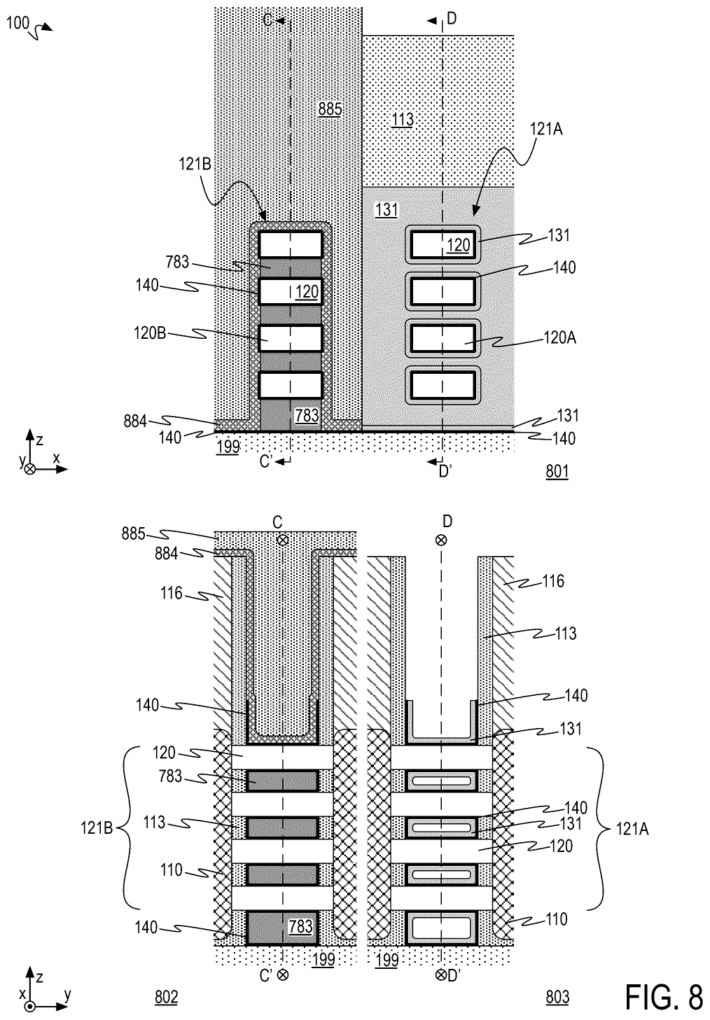

FIG. 8 shows metal 131 exposed (and blocking material 783 absent) around and between nanoribbons 120A and blocking materials 783, 884, 885 masking nanoribbons 120B and second stack 121B in a workpiece or device 100, in accordance with some embodiments, for example, following operations removing blocking material 783 from over first stack 121A and depositing blocking materials 884, 885 over nanoribbons 120B and second stack 121B. FIG. 8 includes view 801 with an x-z viewing plane and views 802, 803 with y-z viewing planes. View 801 shows the orientations of cross-sections C-C′ and D-D′, which are the viewing planes illustrated by views 802, 803, respectively. Note that some of the illustrated structures (e.g., metal 131 and spacer 113 adjacent nanoribbons 120A and stack 121A) are behind (and shown through) the x-z viewing plane.

View 801 illustrates blocking material 783 absent around and between nanoribbons 120A. Template metal 131 is exposed between and around nanoribbons 120A, and nanoribbons 120B are blocked. Blocking material 783 is between nanoribbons 120B, blocking material 884 is conformally over stack 121B of nanoribbons 120B, and blocking material 885 is over stack 121B and material 884. In many embodiments, blocking material 884 is deposited over both stacks 121A, 121B, blocking material 885 is patterned to cover material 884 on stack 121B and leave material 884 exposed on stack 121A, and blocking materials 783, 884 are removed over stack 121A (e.g., exposing template metal 131 on nanoribbons 120A).

Views 802, 803 show blocking material 783 absent around and between nanoribbons 120A. Template metal 131 is exposed between and around nanoribbons 120A, and nanoribbons 120B are blocked. Blocking material 783 is between nanoribbons 120B, blocking material 884 is over stack 121B and conformally on spacer 113, and blocking material 885 is over stack 121B and material 884.

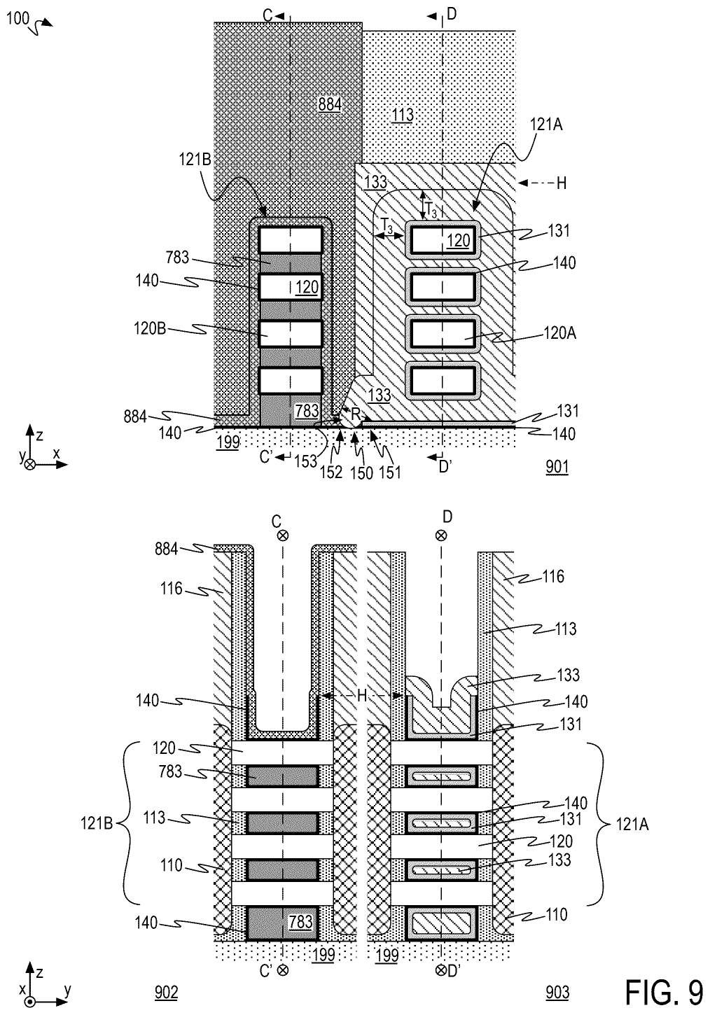

FIG. 9 illustrates WF metal 133 on template metal 131 over, around, and between nanoribbons 120A and blocking materials 783, 884 masking nanoribbons 120B in a workpiece or device 100, in accordance with some embodiments, for example, following a depositing operation 330. FIG. 9 includes view 901 with an x-z viewing plane and views 902, 903 with y-z viewing planes. View 901 shows the orientations of cross-sections C-C′ and D-D′, which are the viewing planes illustrated by views 902, 903, respectively. Note that some of the illustrated structures (e.g., spacer 113 over stack 121A and blocking material 884 over stack 121B) may be behind (and shown through) the x-z viewing plane.

View 901 illustrates WF metal 133 on template metal 131 around and merged between nanoribbons 120A, over substrate 199, and on a sidewall behind and adjacent nanoribbons 120A. WF metal 133 is conformal over template metal 131 around nanoribbons 120A and is merged between nanoribbons 120A. WF metal 133 extends beyond template metal 131 by about thickness T₃ or radius R. For example, WF metal 133 extends beyond template metal 131 by about radius R at an end or edge of metal 131 adjacent gap 150 between edges 151, 152 of insulator 140. WF metal 133 extends beyond template metal 131 on nanoribbons 120A by about thickness T₃ above and to the sides of nanoribbons 120A. WF metal 133 extends above height H beyond template metal 131 on a sidewall of spacer 113 over nanoribbons 120A by about thickness T₃. WF metal 133 may have been grown selectively from template metal 131, and thickness T₃ and radius R may be approximately equal. WF metal 133 extending beyond template metal 131 (and nanoribbons 120A) by thickness T₃ (or radius R) may ensure that nanoribbons 120A (and an associated Vₜ) is shielded from any WF metal subsequently deposited on metal 133. Advantageously, thickness T₃ (or radius R) is sufficiently great to prevent shine-through (e.g., shield) nanoribbons 120A (and an associated Vₜ) from any subsequently deposited WF metal.

View 901 shows blocking material 783 between nanoribbons 120B and blocking material 884 conformally over stack 121B and on a sidewall over stack 121B, but blocking material 885 is absent over stack 121B. In many embodiments, blocking material 885 is removed prior to deposition of WF metal 133. In some such embodiments, a removal etch opens gap 150 between edges 151, 152 of insulator 140. In some embodiments, depositing WF metal 133 (e.g., at operation 330) further degrades exposed insulator 140 at gap 150. In some embodiments, WF metal 133 is on (e.g., contacts) substrate 199 under insulator 140 at gap 150.

Views 902, 903 illustrate WF metal 133 on template metal 131 around and merged between nanoribbons 120A, over substrate 199 adjacent stack 121A, and on a sidewall of spacer 113 over nanoribbons 120A. WF metal 133 is conformal over template metal 131 around nanoribbons 120A and is merged between nanoribbons 120A. WF metal 133 extends above height H beyond template metal 131, conformally on a sidewall of spacer 113 over nanoribbons 120A. Blocking material 783 is between nanoribbons 120B, and blocking material 884 is over stack 121B and conformally on a sidewall of spacer 113 over stack 121B, but blocking material 885 is absent over stack 121B.

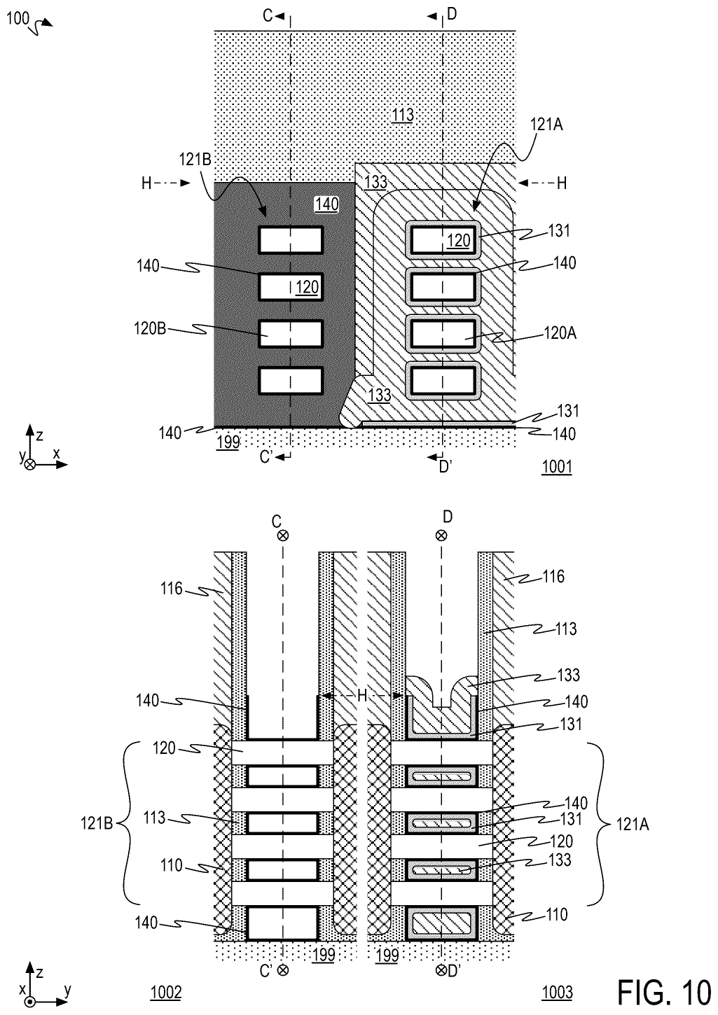

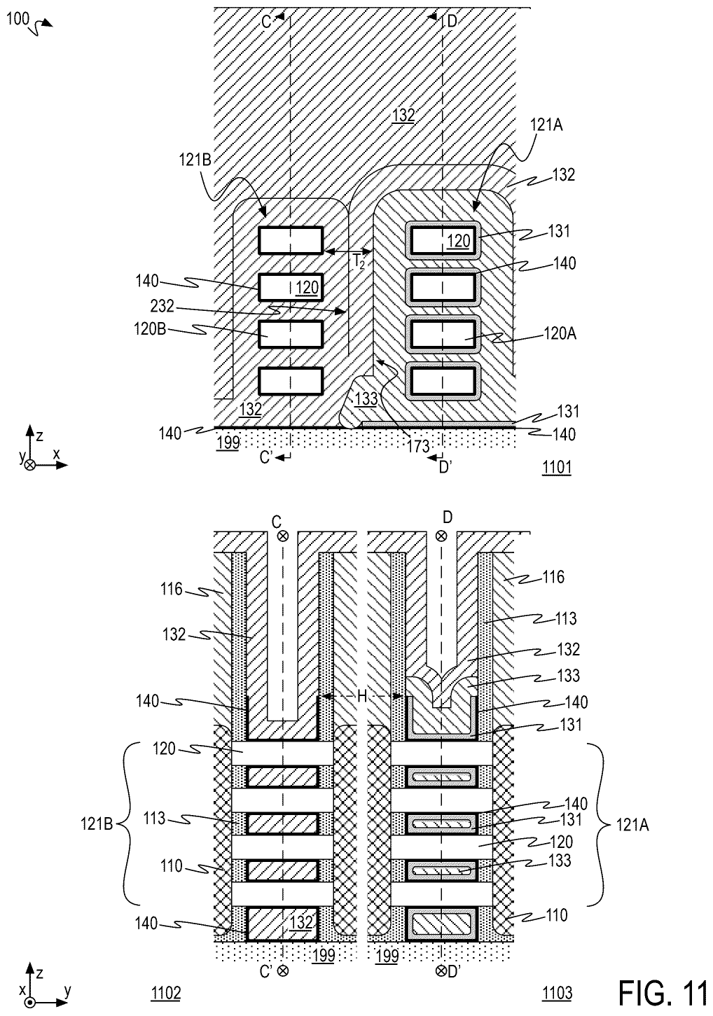

FIG. 10 shows gate insulator 140 exposed around nanoribbons 120B and on a sidewall adjacent stack 121B in a workpiece or device 100, in accordance with some embodiments, for example, following an operation removing blocking materials 783, 884. FIG. 10 includes view 1001 with an x-z viewing plane and views 1002, 1003 with y-z viewing planes. View 1001 shows the orientations of cross-sections C-C′ and D-D′, which are the viewing planes illustrated by views 1002, 1003, respectively. Note that some of the illustrated structures (e.g., spacer 113 over stacks 121 and gate insulator 140 adjacent stack 121B) may be behind (and shown through) the x-z viewing plane.

View 1001 illustrates gate insulator 140 conformally on and around nanoribbons 120B and on a sidewall adjacent stack 121B, exposed without blocking materials 783, 884 over stack 121B. Gate insulator 140 is on a sidewall adjacent stack 121B up to height H. Spacer 113 is exposed above height H on the sidewall adjacent stack 121B. WF metal 133 is conformally on template metal 131 around and between nanoribbons 120A, over substrate 199, and up to and above height H on the sidewall adjacent stack 121A. In many embodiments, blocking materials 783, 884 are each removed by respective isotropic, blanket etches (e.g., a wet etch).

Views 1002, 1003 show WF metal 133 on template metal 131 over, under, and merged between nanoribbons 120A. WF metal 133 is below height H over a midpoint of nanoribbons 120A, but extends above height H beyond template metal 131, conformally on a sidewall of spacer 113 over nanoribbons 120A. Blocking materials 783, 884 are absent over stack 121B.

Returning to FIG. 3, methods 300 continue by depositing a third gate metal at operation 340. The third gate metal may be a second WF metal, e.g., complementary to a first WF metal grown from the template metal over the first channel region(s), to be deposited over the second channel region(s). In many embodiments, the third gate metal is conformally deposited on the gate insulator over the second channel region. In some such embodiments having a stack of nanoribbons for a second channel region, the third gate metal deposited on the gate insulator over the second channel region merges between the nanoribbons and forms a continuous structure of the third gate metal from over an uppermost of the second nanoribbons to under a lowermost of the second nanoribbons. In many embodiments, the third gate metal is conformally deposited on the second gate metal. In some such embodiments, the third gate metal is conformally deposited on a sidewall of the second gate metal, e.g., between the first and second channel regions. In some embodiments, the third gate metal is conformally deposited over or above the second gate metal, e.g., over the first channel region

In some embodiments, conformally depositing the third gate metal on the second gate metal deposits the third gate metal to a thickness of at least 10 nm between the second channel region and the second gate metal over the first channel region, which may be thick enough to completely prevent shine-through of another WF metal (e.g., of opposite or complementary polarity) to the second channel region. In some embodiments, conformally depositing the third gate metal on the second gate metal deposits the third gate metal to a thickness of at least 5 nm between the second channel region and the second gate metal over the first channel region, which may be thick enough to sufficiently prevent shine-through of another WF metal (e.g., of the second gate metal having an opposite or complementary polarity) to the second channel region while minimizing gate volume occupied by the third gate metal (e.g., in a space-constrained gate structure).

The third gate metal may be deposited by any suitable means, such as CVD, ALD, and/or another deposition process. The third gate metal may be deposited to any suitable thickness, for example, with a thickness appropriate for the desired Vₜ-shifting (e.g., for the second channel regions) and for minimizing or preventing shine-through by another WF metal. The third gate metal may include any suitable material(s), such as those described of WF metal 132 (e.g., at FIG. 1A).

In many embodiments, a fourth gate metal is conformally deposited over the second and third gate metals, and a fifth gate metal is deposited over and within the fourth gate metal. The fourth and fifth metals may be conductive materials that couple the second and third gate metals to other electrically conductive structures, such as an interconnect network.

FIG. 11 illustrates WF gate metal 132 conformally on gate insulator 140 around nanoribbons 120B, conformally on a sidewall 173 of WF metal 133 between stacks 121A, 121B, and conformally over WF metal 133 over stack 121A in a workpiece or device 100, in accordance with some embodiments, for example, following a performance of depositing operation 340. FIG. 11 includes view 1101 with an x-z viewing plane and views 1102, 1103 with y-z viewing planes. View 1101 shows the orientations of cross-sections C-C′ and D-D′, which are the viewing planes illustrated by views 1102, 1103, respectively. Note that some of the illustrated structures (e.g., WF gate metal 132 on a sidewall of spacer 113 over stacks 121) may be behind (and shown through) the x-z viewing plane.

View 1101 shows WF gate metal 132 conformally over stack 121B, on, between, and around nanoribbons 120B. WF gate metal 132 is continuous (e.g., merged) between nanoribbons 120B, from above an uppermost nanoribbon 120B to under a lowermost nanoribbon 120B. WF gate metal 132 is also conformally on sidewall 173 of WF metal 133 between stacks 121A, 121B. WF gate metal 132 is continuous between stack 121B and sidewall 173 of WF metal 133, e.g., merged at seam 232 and with thickness T₂ between second stack 121B and WF metal 133 over first stack 121A. Thickness T₂ is advantageously sufficiently great enough to prevent (or at least minimize) shine-through by WF metal 133 to nanoribbons 120B (and an associated Vₜ). WF gate metal 132 is also conformally on WF metal 133 over stack 121A. WF gate metal 132 is also on a sidewall over stacks 121A, 121B, behind the x-z viewing plane.

View 1102 illustrates WF gate metal 132 conformally on, between, and around nanoribbons 120B and over stack 121B. WF gate metal 132 is continuous (e.g., merged) between nanoribbons 120B, from above an uppermost nanoribbon 120B to under a lowermost nanoribbon 120B. WF gate metal 132 is also conformally on sidewalls of spacer 113 over stack 121B.

View 1103 shows WF gate metal 132 conformally on sidewalls of spacer 113 over stack 121A. WF gate metal 132 is conformally on (e.g., in contact with) WF metal 133 over stack 121A, from below height H over a midpoint of nanoribbons 120A, to above height H on sidewalls of spacer 113 over metals 131, 133.

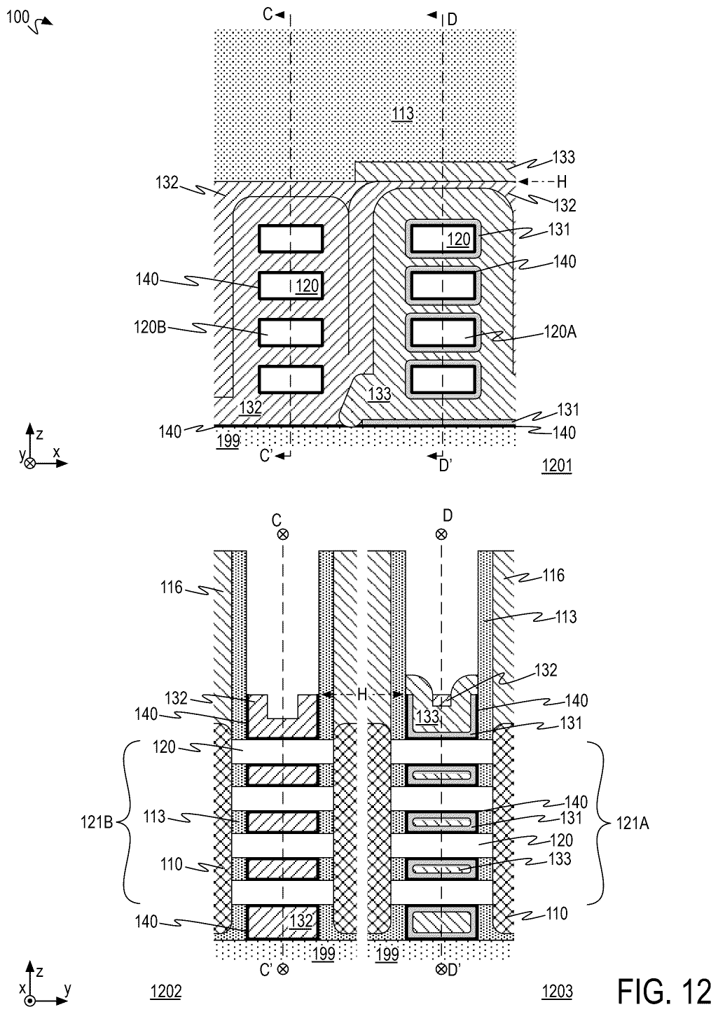

FIG. 12 illustrates WF metal 132 conformally on gate insulator 140 around nanoribbons 120B below height H and conformally on WF metal 133 over stack 121A below height H in a workpiece or device 100, in accordance with some embodiments, for example, following a recessing operation. FIG. 12 includes view 1201 with an x-z viewing plane and views 1202, 1203 with y-z viewing planes. View 1201 shows the orientations of cross-sections C-C′ and D-D′, which are the viewing planes illustrated by views 1202, 1203, respectively. Note that some of the illustrated structures (e.g., WF metal 132 on a sidewall of spacer 113 over stack 121B and WF metal 133 on a sidewall of spacer 113 over stack 121A) may be behind (and shown through) the x-z viewing plane.

View 1201 shows WF metal 132 on a sidewall of spacer 113, below height H and over and behind stack 121B. WF metal 133 is on a sidewall of spacer 113, above height H and over and behind stack 121A. In many embodiments, WF metal 132 is recessed (e.g., down to height H) with a blocking material deposited (e.g., and patterned) to about height H, exposed portions of metal 132 are removed above the blocking material, and blocked portions of metal 132 are retained (e.g., much as described of the recessing of metal 131).

View 1202 illustrates WF gate metal 132 conformally on sidewalls of spacer 113 over stack 121B, but absent above height H. WF gate metal 132 is conformally on, between, and around nanoribbons 120B and over stack 121B, up to height H. WF gate metal 132 is continuous (e.g., merged) between nanoribbons 120B, from above an uppermost nanoribbon 120B to under a lowermost nanoribbon 120B, over substrate 199.

View 1203 shows WF metal 132 absent from sidewalls of spacer 113 over stack 121A. WF metal 132 is only conformally on WF metal 133 below height H (e.g., over stack 121A at a midpoint of nanoribbons 120A).

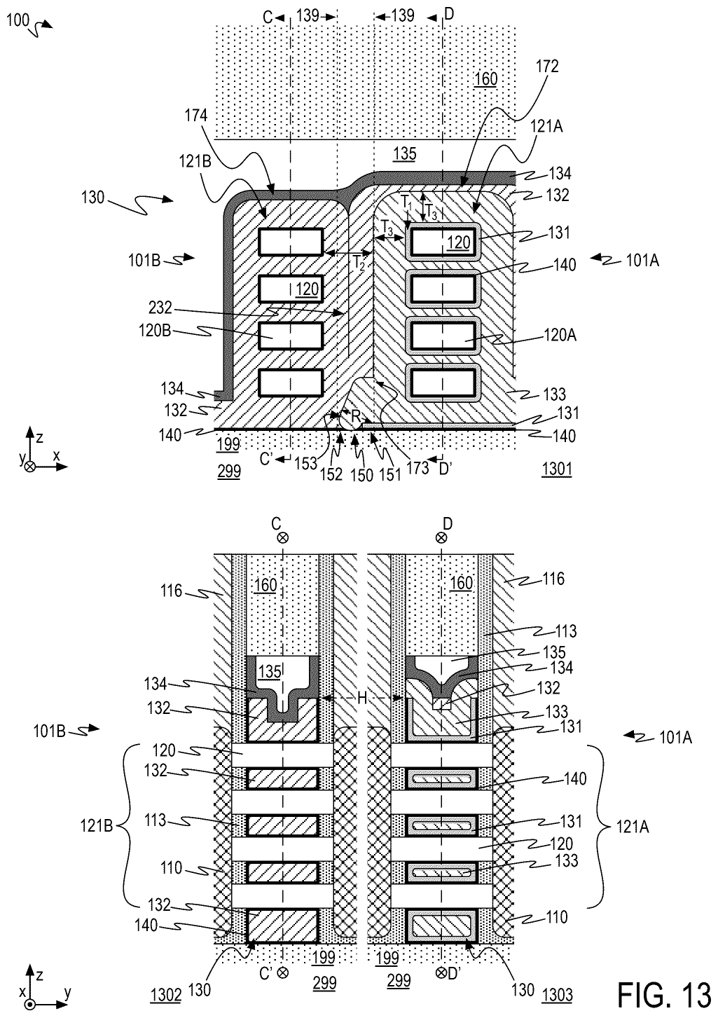

FIG. 13 illustrates gate structure 130 having metals 134, 135 conformally on and over metal 132 over stacks 121 in IC device 100, in accordance with some embodiments, for example, following a depositing operation. FIG. 13 includes view 1301 with an x-z viewing plane and views 1302, 1303 with y-z viewing planes. View 1301 shows the orientations of cross-sections C-C′ and D-D′, which are the viewing planes illustrated by views 1302, 1303, respectively.

View 1301 shows liner metal 134 conformally on and over metal 132 over stacks 121 and fill metal 135 conformally on and over metal 134. Insulator 160 is over metals 134, 135. In many embodiments, fourth gate metal 134 is conformally deposited over the gate metals 132, 133, and a fifth gate metal 135 is deposited over and within fourth gate metal 134. Fourth and fifth metals 134, 135 may be conductive materials that couple second and third gate metals 132, 133 to other electrically conductive structures, such as an interconnect network. IC device 100 may be coupled to one or more power supplies on or through a host component 299 coupled to substrate 199.

View 1302 illustrates liner metal 134 conformally on and over metal 132 (and conformally on sidewalls of spacer 113) over stack 121B and fill metal 135 conformally on and contained within liner metal 134. Insulator 160 is on and over metals 134, 135.

View 1303 liner metal 134 conformally on and over metals 132, 133 (and conformally on sidewalls of spacer 113) over stack 121A and fill metal 135 conformally on and contained within liner metal 134. Insulator 160 is on and over metals 134, 135.

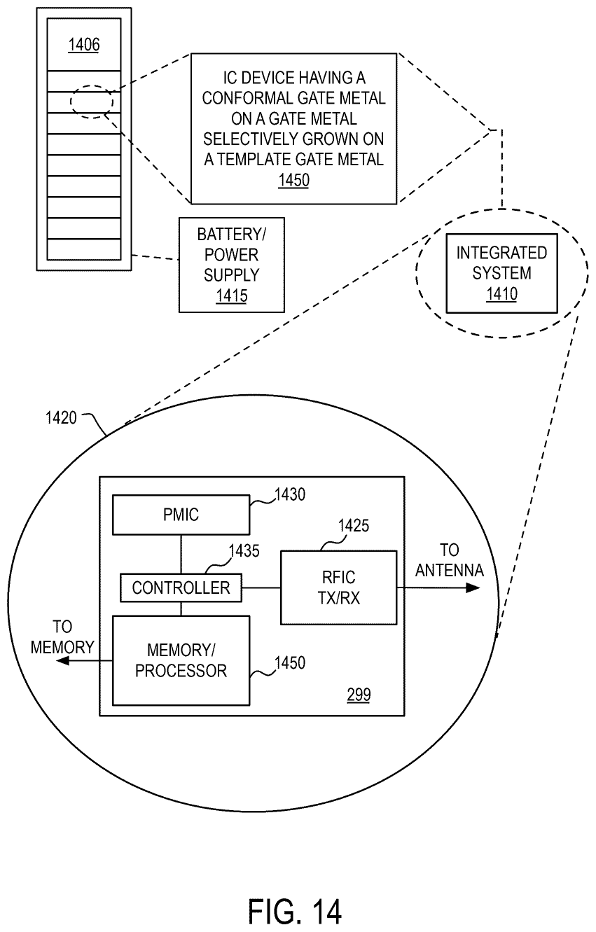

FIG. 14 illustrates a diagram of an example data server machine 1406 employing an IC device having a first WF gate metal selectively deposited on a template gate metal and a second WF gate metal conformally deposited on the first WF gate metal, in accordance with some embodiments. Server machine 1406 may be any commercial server, for example, including any number of high-performance computing platforms disposed within a rack and networked together for electronic data processing, which in the exemplary embodiment includes one or more devices 1450 having a first WF gate metal selectively deposited on a template gate metal and a second WF gate metal conformally deposited on the first WF gate metal.

Also as shown, server machine 1406 includes a battery and/or power supply 1415 to provide power to devices 1450, and to provide, in some embodiments, power delivery functions such as power regulation. Devices 1450 may be deployed as part of a package-level integrated system 1410. Integrated system 1410 is further illustrated in the expanded view 1420. In the exemplary embodiment, devices 1450 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 1450 is a microprocessor including a static RAM (SRAM) cache memory. As shown, device 1450 may be an IC device having a first WF gate metal selectively deposited on a template gate metal and a second WF gate metal conformally deposited on the first WF gate metal, as discussed herein. Device 1450 may be further coupled to (e.g., communicatively coupled to) a board, an interposer, or a host component 299 along with, one or more of a power management IC (PMIC) 1430, RF (wireless) IC (RFIC) 1425 including a wideband RF (wireless) transmitter and/or receiver (TX/RX) (e.g., including a digital baseband and an analog front end module further includes a power amplifier on a transmit path and a low noise amplifier on a receive path), and a controller 1435 thereof. In some embodiments, RFIC 1425, PMIC 1430, controller 1435, and device 1450 include having a first WF gate metal selectively deposited on a template gate metal and a second WF gate metal conformally deposited on the first WF gate metal.

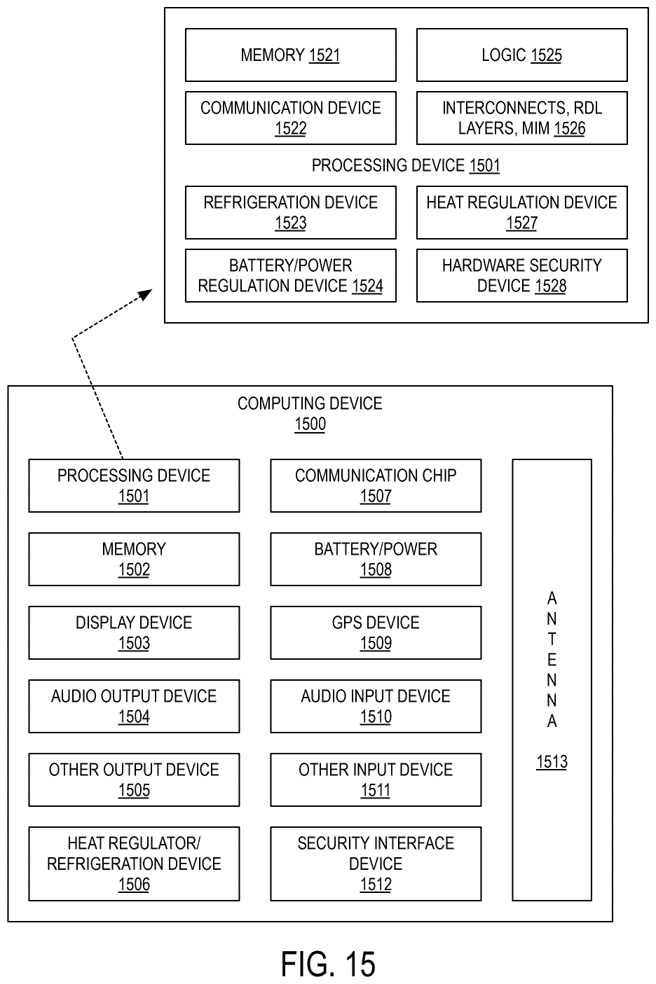

FIG. 15 is a block diagram of an example computing device 1500, in accordance with some embodiments. For example, one or more components of computing device 1500 may include any of the devices or structures discussed herein. A number of components are illustrated in FIG. 15 as being included in computing device 1500, but any one or more of these components may be omitted or duplicated, as suitable for the application. In some embodiments, some or all of the components included in computing device 1500 may be attached to one or more printed circuit boards (e.g., a motherboard). In some embodiments, various ones of these components may be fabricated onto a single system-on-a-chip (SoC) die. Additionally, in various embodiments, computing device 1500 may not include one or more of the components illustrated in FIG. 15, but computing device 1500 may include interface circuitry for coupling to the one or more components. For example, computing device 1500 may not include a display device 1503, but may include display device interface circuitry (e.g., a connector and driver circuitry) to which display device 1503 may be coupled. In another set of examples, computing device 1500 may not include an audio output device 1504, other output device 1505, global positioning system (GPS) device 1509, audio input device 1510, or other input device 1511, but may include audio output device interface circuitry, other output device interface circuitry, GPS device interface circuitry, audio input device interface circuitry, audio input device interface circuitry, to which audio output device 1504, other output device 1505, GPS device 1509, audio input device 1510, or other input device 1511 may be coupled.

Computing device 1500 may include a processing device 1501 (e.g., one or more processing devices). As used herein, the term “processing device” or “processor” indicates a device that processes electronic data from registers and/or memory to transform that electronic data into other electronic data that may be stored in registers and/or memory. Processing device 1501 may include a memory 1521, a communication device 1522, a refrigeration device 1523, a battery/power regulation device 1524, logic 1525, interconnects 1526 (i.e., optionally including redistribution layers (RDL) or metal-insulator-metal (MIM) devices), a heat regulation device 1527, and a hardware security device 1528.

Processing device 1501 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 1500 may include a memory 1502, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1502 includes memory that shares a die with processing device 1501. This memory may be used as cache memory and may include embedded dynamic random-access memory (eDRAM) or spin transfer torque magnetic random-access memory (STT-MRAM).

Computing device 1500 may include a heat regulation/refrigeration device 1506. Heat regulation/refrigeration device 1506 may maintain processing device 1501 (and/or other components of computing device 1500) at a predetermined low temperature during operation.

In some embodiments, computing device 1500 may include a communication chip 1507 (e.g., one or more communication chips). For example, the communication chip 1507 may be configured for managing wireless communications for the transfer of data to and from computing device 1500. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 1507 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1507 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network.

Communication chip 1507 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1507 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1507 may operate in accordance with other wireless protocols in other embodiments. Computing device 1500 may include an antenna 1513 to facilitate wireless communications and/or to receive other wireless communications (such as AM or FM radio transmissions).

In some embodiments, communication chip 1507 may manage wired communications, such as electrical, optical, or any other suitable communication protocols (e.g., the Ethernet). As noted above, communication chip 1507 may include multiple communication chips. For instance, a first communication chip 1507 may be dedicated to shorter-range wireless communications such as Wi-Fi or Bluetooth, and a second communication chip 1507 may be dedicated to longer-range wireless communications such as GPS, EDGE, GPRS, CDMA, WiMAX, LTE, EV-DO, or others. In some embodiments, a first communication chip 1507 may be dedicated to wireless communications, and a second communication chip 1507 may be dedicated to wired communications.

Computing device 1500 may include battery/power circuitry 1508. Battery/power circuitry 1508 may include one or more energy storage devices (e.g., batteries or capacitors) and/or circuitry for coupling components of computing device 1500 to an energy source separate from computing device 1500 (e.g., AC line power).

Computing device 1500 may include a display device 1503 (or corresponding interface circuitry, as discussed above). Display device 1503 may include any visual indicators, such as a heads-up display, a computer monitor, a projector, a touchscreen display, a liquid crystal display (LCD), a light-emitting diode display, or a flat panel display, for example.

Computing device 1500 may include an audio output device 1504 (or corresponding interface circuitry, as discussed above). Audio output device 1504 may include any device that generates an audible indicator, such as speakers, headsets, or earbuds, for example.

Computing device 1500 may include an audio input device 1510 (or corresponding interface circuitry, as discussed above). Audio input device 1510 may include any device that generates a signal representative of a sound, such as microphones, microphone arrays, or digital instruments (e.g., instruments having a musical instrument digital interface (MIDI) output).

Computing device 1500 may include a GPS device 1509 (or corresponding interface circuitry, as discussed above). GPS device 1509 may be in communication with a satellite-based system and may receive a location of computing device 1500, as known in the art.

Computing device 1500 may include other output device 1505 (or corresponding interface circuitry, as discussed above). Examples of the other output device 1505 may include an audio codec, a video codec, a printer, a wired or wireless transmitter for providing information to other devices, or an additional storage device.

Computing device 1500 may include other input device 1511 (or corresponding interface circuitry, as discussed above). Examples of the other input device 1511 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1500 may include a security interface device 1512. Security interface device 1512 may include any device that provides security measures for computing device 1500 such as intrusion detection, biometric validation, security encode or decode, access list management, malware detection, or spyware detection.

Computing device 1500, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-15. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a first stack of first nanoribbons over a substrate, wherein a first gate insulator is over the first nanoribbons, and a first metal is on the first gate insulator, is over the substrate, and is around and between the first nanoribbons, a second stack of second nanoribbons over the substrate, wherein a second gate insulator is over the second nanoribbons, a second metal is on the second gate insulator and around and between the second nanoribbons, and the second metal is separate from the first metal, and a gate structure over the first and second stacks, the gate structure including the first metal, the second metal, and a third metal, wherein the third metal is around and between the first nanoribbons, is between the first and second stacks, is in contact with both the first and second metals, and extends beyond the first metal over the substrate.

In one or more second embodiments, further to the first embodiments, the first gate insulator is over the substrate under the first stack, the first metal is on the first gate insulator over the substrate, the third metal is conformally on the first metal on the first gate insulator over the substrate, and the third metal contacts the first gate insulator over the substrate beyond the first metal.

In one or more third embodiments, further to the first or second embodiments, a continuous portion of the second metal is on the second gate insulator over and around the second nanoribbons and is conformally on a sidewall of the third metal.

In one or more fourth embodiments, further to the first through third embodiments, the continuous portion of the second metal is on the third metal over the first stack, the gate structure includes fourth and fifth metals over the first and second stacks, a continuous layer of the fourth metal is over the first and second stacks, the fifth metal is over the fourth metal, and the continuous portion of the second metal is between the third metal and the fourth metal.

In one or more fifth embodiments, further to the first through fourth embodiments, fourth and fifth metals are between first and second sectors of a continuous portion of the second metal, a continuous layer of the fourth metal is conformally on the continuous portion, a third sector of the continuous layer is on the first sector, a fourth sector of the continuous layer is on the second sector, and the fifth metal is between the third and fourth sectors.

In one or more sixth embodiments, further to the first through fifth embodiments, the first gate insulator is on the substrate under the first stack, the second gate insulator is on the substrate under the second stack, and the third metal contacts the substrate in a gap between the first gate insulator and the second gate insulator.

In one or more seventh embodiments, further to the first through sixth embodiments, the first gate insulator at a first edge of the gap includes a same composition as the second gate insulator at a second edge of the gap.

In one or more eighth embodiments, further to the first through seventh embodiments, the third metal includes a thickness of at least 5 nm between the first metal on the first gate insulator over the first nanoribbons, and the second metal on the second gate insulator over the second nanoribbons.

In one or more ninth embodiments, an apparatus includes a first stack of first nanoribbons over a substrate and of a first conductivity type, wherein a first gate insulator is on the first nanoribbons and on the substrate under the first stack, and a first metal is on the first gate insulator and around the first nanoribbons, a second stack of second nanoribbons over the substrate and of a second conductivity type, complementary to the first conductivity type, wherein a second gate insulator is on the second nanoribbons and on the substrate under the second stack, and a second metal is on the second gate insulator, around and between the second nanoribbons, and a gate structure over the substrate and the first and second stacks, the gate structure including the first and second gate insulators, the first and second metals, and a third metal, wherein the third metal is on the first metal, the first metal is between the third metal and the substrate, the third metal separates the first and second metals, and the third metal is around and between the first nanoribbons.

In one or more tenth embodiments, further to the ninth embodiments, a continuous portion of the second metal is on the second gate insulator over and around the second nanoribbons and is conformally on a sidewall of the third metal.

In one or more eleventh embodiments, further to the ninth or tenth embodiments, the continuous portion of the second metal is conformally on the third metal over the first stack, the gate structure includes fourth and fifth metals over the first and second stacks, a continuous layer of the fourth metal is over the first and second stacks, the fifth metal is over the fourth metal, and the continuous portion of the second metal is between the third metal and the fourth metal.

In one or more twelfth embodiments, further to the ninth through eleventh embodiments, the third metal is conformally on the first metal over the substrate and under the first stack, the third metal extends over the substrate beyond the first metal, and the third metal contacts the first gate insulator on the substrate beyond the first metal.

In one or more thirteenth embodiments, further to the ninth through twelfth embodiments, the third metal is on the substrate between the first stack and the second stack, the third metal contacting the substrate in a gap between the first gate insulator under the first stack and the second gate insulator under the second stack.

In one or more fourteenth embodiments, further to the ninth through thirteenth embodiments, the first gate insulator at a first edge of the gap includes a same composition as the second gate insulator at a second edge of the gap.

In one or more fifteenth embodiments, further to the ninth through fourteenth embodiments, fourth and fifth metals are between first and second sectors of a continuous section of the second metal, a continuous layer of the fourth metal is conformally on the continuous portion, a third sector of the continuous layer is on the first sector, a fourth sector of the continuous layer is on the second sector, and the fifth metal is between the third and fourth sectors.

In one or more sixteenth embodiments, a method includes depositing a first gate metal on a gate insulator over a first channel region, wherein the first channel region and a second channel region are over a substrate, and the gate insulator is over the first and second channel regions and the substrate, selectively depositing a second gate metal on the first gate metal, and conformally depositing a third gate metal on the second gate metal and on the gate insulator over the second channel region.

In one or more seventeenth embodiments, further to the sixteenth embodiments, also including conformally depositing the gate insulator over the first and second channel regions and over the substrate, wherein the gate insulator is continuous over the substrate under and between the first and second channel regions, and the depositing the first gate metal on the gate insulator deposits the first gate metal on the gate insulator over the first channel region and over the substrate under the first channel region.

In one or more eighteenth embodiments, further to the sixteenth or seventeenth embodiments, the selectively depositing the second gate metal on the first gate metal deposits the second gate metal conformally on the first gate metal and on the gate insulator over the substrate beyond the first gate metal, and the depositing the second gate metal conformally on the gate insulator deposits the second gate metal on the substrate in a gap in the gate insulator over the substrate and between the first and second channel regions.

In one or more nineteenth embodiments, further to the sixteenth through eighteenth embodiments, the selectively depositing the second gate metal on the first gate metal deposits the second gate metal to a thickness of at least 5 nm, the first channel region includes a stack of nanoribbons with the first gate metal and the gate insulator around the nanoribbons, the selectively depositing the second gate metal on the first gate metal deposits the second gate metal conformally around the nanoribbons and merging between the nanoribbons, and the conformally depositing the third gate metal on the second gate metal deposits the third gate metal at least 5 nm from the first gate metal on the gate insulator over the first channel region.

In one or more twentieth embodiments, further to the sixteenth through nineteenth embodiments, also including patterning the first gate metal before selectively depositing the second gate metal.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a first stack of first nanoribbons over a substrate, wherein a first gate insulator is over the first nanoribbons, and a first metal is on the first gate insulator, is over the substrate, and is around and between the first nanoribbons;
a second stack of second nanoribbons over the substrate, wherein a second gate insulator is over the second nanoribbons, a second metal is on the second gate insulator and around and between the second nanoribbons, and the second metal is separate from the first metal; and
a gate structure over the first and second stacks, the gate structure comprising the first metal, the second metal, and a third metal, wherein the third metal is around and between the first nanoribbons, is between the first and second stacks, is in contact with both the first and second metals, and extends beyond the first metal over the substrate.

2. The apparatus of claim 1, wherein:
the first gate insulator is over the substrate under the first stack;
the first metal is on the first gate insulator over the substrate;
the third metal is conformally on the first metal on the first gate insulator over the substrate; and
the third metal contacts the first gate insulator over the substrate beyond the first metal.

3. The apparatus of claim 1, wherein a continuous portion of the second metal is on the second gate insulator over and around the second nanoribbons and is conformally on a sidewall of the third metal.

4. The apparatus of claim 3, wherein:
the continuous portion of the second metal is on the third metal over the first stack;
the gate structure comprises fourth and fifth metals over the first and second stacks;
a continuous layer of the fourth metal is over the first and second stacks;
the fifth metal is over the fourth metal; and
the continuous portion of the second metal is between the third metal and the fourth metal.

5. The apparatus of claim 1, wherein:
fourth and fifth metals are between first and second sectors of a continuous portion of the second metal;
a continuous layer of the fourth metal is conformally on the continuous portion;
a third sector of the continuous layer is on the first sector;
a fourth sector of the continuous layer is on the second sector; and
the fifth metal is between the third and fourth sectors.

6. The apparatus of claim 1, wherein:
the first gate insulator is on the substrate under the first stack;
the second gate insulator is on the substrate under the second stack; and
the third metal contacts the substrate in a gap between the first gate insulator and the second gate insulator.

7. The apparatus of claim 6, wherein the first gate insulator at a first edge of the gap comprises a same composition as the second gate insulator at a second edge of the gap.

8. The apparatus of claim 1, wherein the third metal comprises a thickness of at least 5 nm between:
the first metal on the first gate insulator over the first nanoribbons; and
the second metal on the second gate insulator over the second nanoribbons.

9. An apparatus, comprising:
a first stack of first nanoribbons over a substrate and of a first conductivity type, wherein a first gate insulator is on the first nanoribbons and on the substrate under the first stack, and a first metal is on the first gate insulator and around the first nanoribbons;
a second stack of second nanoribbons over the substrate and of a second conductivity type, complementary to the first conductivity type, wherein a second gate insulator is on the second nanoribbons and on the substrate under the second stack, and a second metal is on the second gate insulator, around and between the second nanoribbons; and
a gate structure over the substrate and the first and second stacks, the gate structure comprising the first and second gate insulators, the first and second metals, and a third metal, wherein the third metal is on the first metal, the first metal is between the third metal and the substrate, the third metal separates the first and second metals, and the third metal is around and between the first nanoribbons.

10. The apparatus of claim 9, wherein a continuous portion of the second metal is on the second gate insulator over and around the second nanoribbons and is conformally on a sidewall of the third metal.

11. The apparatus of claim 10, wherein:
the continuous portion of the second metal is conformally on the third metal over the first stack;
the gate structure comprises fourth and fifth metals over the first and second stacks;
a continuous layer of the fourth metal is over the first and second stacks;
the fifth metal is over the fourth metal; and
the continuous portion of the second metal is between the third metal and the fourth metal.

12. The apparatus of claim 10, wherein:
the third metal is conformally on the first metal over the substrate and under the first stack;
the third metal extends over the substrate beyond the first metal; and
the third metal contacts the first gate insulator on the substrate beyond the first metal.

13. The apparatus of claim 12, wherein the third metal is on the substrate between the first stack and the second stack, the third metal contacting the substrate in a gap between the first gate insulator under the first stack and the second gate insulator under the second stack.

14. The apparatus of claim 13, wherein the first gate insulator at a first edge of the gap comprises a same composition as the second gate insulator at a second edge of the gap.

15. The apparatus of claim 13, wherein:
fourth and fifth metals are between first and second sectors of a continuous section of the second metal;
a continuous layer of the fourth metal is conformally on the continuous portion;
a third sector of the continuous layer is on the first sector;
a fourth sector of the continuous layer is on the second sector; and
the fifth metal is between the third and fourth sectors.

16. A method, comprising:
depositing a first gate metal on a gate insulator over a first channel region, wherein the first channel region and a second channel region are over a substrate, and the gate insulator is over the first and second channel regions and the substrate;
selectively depositing a second gate metal on the first gate metal; and
conformally depositing a third gate metal on the second gate metal and on the gate insulator over the second channel region.

17. The method of claim 16, further comprising conformally depositing the gate insulator over the first and second channel regions and over the substrate, wherein:
the gate insulator is continuous over the substrate under and between the first and second channel regions; and
the depositing the first gate metal on the gate insulator deposits the first gate metal on the gate insulator over the first channel region and over the substrate under the first channel region.

18. The method of claim 17, wherein:
the selectively depositing the second gate metal on the first gate metal deposits the second gate metal conformally on the first gate metal and on the gate insulator over the substrate beyond the first gate metal; and
the depositing the second gate metal conformally on the gate insulator deposits the second gate metal on the substrate in a gap in the gate insulator over the substrate and between the first and second channel regions.

19. The method of claim 16, wherein:
the selectively depositing the second gate metal on the first gate metal deposits the second gate metal to a thickness of at least 5 nm;
the first channel region comprises a stack of nanoribbons with the first gate metal and the gate insulator around the nanoribbons;
the selectively depositing the second gate metal on the first gate metal deposits the second gate metal conformally around the nanoribbons and merging between the nanoribbons; and
the conformally depositing the third gate metal on the second gate metal deposits the third gate metal at least 5 nm from the first gate metal on the gate insulator over the first channel region.

20. The method of claim 16, further comprising patterning the first gate metal before selectively depositing the second gate metal.
